(19) United States
(12) Patent Application Publication
(10) Pub. No.: US 2024/0355624 A1
(43) Pub. Date: Oct. 24, 2024

(54) IN-SITU CORE PROTECTION IN MULTI-PATTERNING

(71) Applicant: Lam Research Corporation, Fremont, CA (US)

(72) Inventors: Nuoya Yang, Frisco, TX (US); Pulkit Agarwal, Beaverton, OR (US); Jennifer Leigh Petraglia, Lake Oswego, OR (US); Ching-Yun Chang, West Linn, OR (US); Jeongseok Ha, Portland, OR (US)

(21) Appl. No.: 18/684,591

(22) PCT Filed: Aug. 22, 2022
(86) PCT No.: PCT/US2022/075296

§ 371 Date: Feb. 16, 2024

Related U.S. Application Data
(60) Provisional application No. 63/260,536, filed on Aug. 24, 2021.

(51) Int. Cl. H01L 21/033; C23C 16/26; C23C 16/40; C23C 16/455; C23C 16/50; C23C 16/52; C23C 16/56; H01L 21/02

(52) U.S. Cl. CPC H01L 21/0337; C23C 16/26; C23C 16/401; C23C 16/4554; C23C 16/50; C23C 16/52; C23C 16/56; H01L 21/0228

(57) ABSTRACT

Methods and apparatuses for forming spacer material for multiple patterning schemes by depositing a sacrificial layer on a carbon-containing mandrel during a multiple patterning scheme prior to depositing a spacer material and removing the sacrificial layer while depositing a spacer on the carbon-containing mandrel, and/or by forming at least initial layers of a spacer material directly on a mandrel using a soft atomic layer deposition process involving plasma treatment during the atomic layer deposition are provided.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

Fabrication of advanced integrated circuits often involves patterning of small features in high volume manufacturing of semiconductors. Multiple patterning techniques may enable feature size scaling beyond lithographic techniques. Self-aligned double and quad patterning are examples of multiple patterning techniques.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

One aspect involves a method for processing substrates, the method including: depositing a sacrificial layer directly on exposed surfaces of a mandrel on a semiconductor substrate; and introducing a spacer material precursor and oxygen-containing reactant and igniting a first plasma to simultaneously remove the sacrificial layer and deposit a spacer material on the exposed surfaces of the mandrel.

In various embodiments, the sacrificial layer includes carbon. For example, in some embodiments, the sacrificial layer includes amorphous carbon.

In various embodiments, the sacrificial layer is deposited by plasma-enhanced chemical vapor deposition.

In various embodiments, the sacrificial layer is deposited conformally.

In various embodiments, the sacrificial layer is deposited to preferentially deposit thicker sacrificial layer material at or near the top of the mandrel than a bottom of the mandrel.

In various embodiments, the sacrificial layer has a density less than a density of the mandrel.

In various embodiments, the sacrificial layer has a modulus less than a modulus of the mandrel.

In various embodiments, the sacrificial layer is deposited using a carbon-containing precursor. For example, in some embodiments, the carbon-containing precursor is an alkane or alkene. In some embodiments, the carbon-containing precursor is selected from the group consisting of methane and acetylene.

In various embodiments, the sacrificial layer is deposited using a precursor that can be exposed to silicon-containing and oxygen-containing reactants without reacting.

In various embodiments, the method also includes introducing the spacer material precursor and the oxygen-containing reactant in temporally separated pulses of a cycle, whereby a cycle includes one pulse of the spacer material precursor and one pulse of the oxygen-containing reactant; and igniting a second plasma, and the second plasma is ignited using a plasma power greater than plasma power used in the first plasma. In some embodiments, the second plasma is ignited every n cycles of the temporally separated pulses. In some embodiments, n is an integer equal to or greater than 1. In some embodiments, the second plasma has a plasma energy greater than about 25000 J. In some embodiments, the second plasma densifies the spacer material.

In various embodiments, the semiconductor substrate is housed in a chamber having a pedestal set to a pedestal temperature and the pedestal temperature when depositing the sacrificial layer is the same as the pedestal temperature when introducing the spacer material precursor and oxygen-containing reactant. For example in some embodiments, the pedestal temperature is less than about 50° C. In some embodiments, the pedestal temperature is less than about 30° C.

In various embodiments, the method also includes directionally etching the spacer material from horizontal regions of the spacer material, and selectively removing the mandrel to leave free-standing symmetrical spacers to be used as a mask.

In various embodiments, surfaces of the mandrel are not consumed during the introducing of the spacer material precursor and the oxygen-containing reactant.

In various embodiments, the first plasma is ignited at a plasma power per substrate area of greater than about 0.0007 W/mm².

In various embodiments, less than about 10 Å of the mandrel is consumed during introducing of the spacer material precursor and the oxygen-containing reactant and the igniting of the first plasma.

In various embodiments, the sacrificial layer is entirely removed during the introducing of the spacer material precursor and the oxygen-containing reactant and the igniting the first plasma.

In various embodiments, the depositing the sacrificial layer and the introducing of the spacer material precursor and the oxygen-containing reactant and the igniting the first plasma are performed without breaking vacuum.

In various embodiments, the depositing the sacrificial layer and the introducing of the spacer material precursor and the oxygen-containing reactant and the igniting the first plasma are performed in the same chamber.

In various embodiments, the mandrel includes carbon.

In various embodiments, the spacer material includes silicon oxide.

Another aspect involves an apparatus including: a process chamber including a heated pedestal for holding a substrate; one or more gas sources for each containing one or more gases selected from the group consisting of carbon-containing gases, silicon-containing gases, and oxygen-containing gases; at least one outlet for coupling to a vacuum; and a controller for controlling operations in the apparatus, including machine-readable instructions for: causing introduction of a carbon-containing gas at a pedestal temperature of less than about 50° C.; after causing introduction of the carbon-containing gas, causing introduction of a silicon-containing precursor and an oxygen-containing reactant while maintaining the same pedestal temperature; and generating a plasma while the oxygen-containing reactant is introduced.

Another aspect involves a method for processing substrates, the method including: providing a semiconductor substrate; depositing one or more layers of spacer material on the semiconductor substrate using atomic layer deposition, such that atomic layer deposition is performed in cycles, a cycle including exposing the semiconductor substrate to a deposition precursor to adsorb the deposition precursor to a surface of the substrate to form an adsorbed deposition precursor and converting the adsorbed deposition precursor to spacer material using a first plasma ignited using a plasma power of less than about 500 W; and after at least one cycle atomic layer deposition, exposing the spacer material to a second plasma at a plasma energy of greater than about 25000 J to form a densified spacer material.

In various embodiments, exposing the spacer material to the second plasma is performed after every n cycles of atomic layer deposition. In some embodiments n is an integer greater than or equal to 1.

In various embodiments, the method also includes prior to depositing the one or more layers of spacer material, depositing a sacrificial layer directly on exposed surfaces of a mandrel on a semiconductor substrate, such that depositing the one or more layers of spacer material simultaneously deposits spacer material on the exposed surfaces of the mandrel and partially removes the sacrificial layer.

In various embodiments, the second plasma is ignited in an environment including a gas selected from the group consisting of argon, helium, nitrogen, and combinations thereof.

In various embodiments, the method also includes, after depositing the densified spacer material, depositing a second spacer material on the densified spacer material using atomic layer deposition using a plasma power of greater than about 500 W.

In various embodiments, the spacer material is deposited on exposed surfaces of the semiconductor substrate.

In some embodiments, exposed surfaces of the semiconductor substrate include material selected from the group consisting of nitrides, photoresists, germanium antimony tellurium, chalcoxides, and combinations thereof.

These and other aspects are described further below with reference to the drawings.

### BRIEF DESCRIPTION OF THE DRAWINGS

FIGS. 1A-1D are schematic illustrations of substrates in an example of a double patterning scheme.

FIGS. 2A-2D are schematic illustrations of substrates in an example of a double patterning scheme.

FIGS. 3A and 3B are process flow diagrams depicting operations for methods performed in accordance with certain disclosed embodiments.

FIGS. 4A-4F are schematic illustrations of substrates in an example of a patterning scheme performed in accordance with certain disclosed embodiments.

FIG. 5 is a schematic diagram of an example process chamber for performing certain disclosed embodiments.

FIG. 6 is a schematic diagram of an example process tool for performing certain disclosed embodiments.

FIG. 7 is a chart showing thickness of substrates processed in an experiment.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Patterning methods are used in many semiconductor manufacturing processes. In particular, multiple patterning has been used to extend lithographic technology beyond its optical limits. Double patterning and quad patterning are example technologies used to extend lithographic technology beyond its optical limits and double patterning is now used in the industry for pitches less than about 80 nm. Current double patterning technologies use sidewall spacers with two masking steps to pattern trenches. Methods of double patterning, particularly line patterning, in both positive and negative double patterning processes have involved the use of spacers and masks. Spacers can be deposited by plasma enhanced atomic layer deposition (PEALD) on a patterned core or mandrels and may be used to create a smaller pitch pattern. As devices shrink and the pitch decreases, issues such as spacer leaning, line bending, and patterned spacer collapse arise, which can thereby cause device failure. In particular, pitch walking due to spacer leaning is observed when the mandrels are removed.

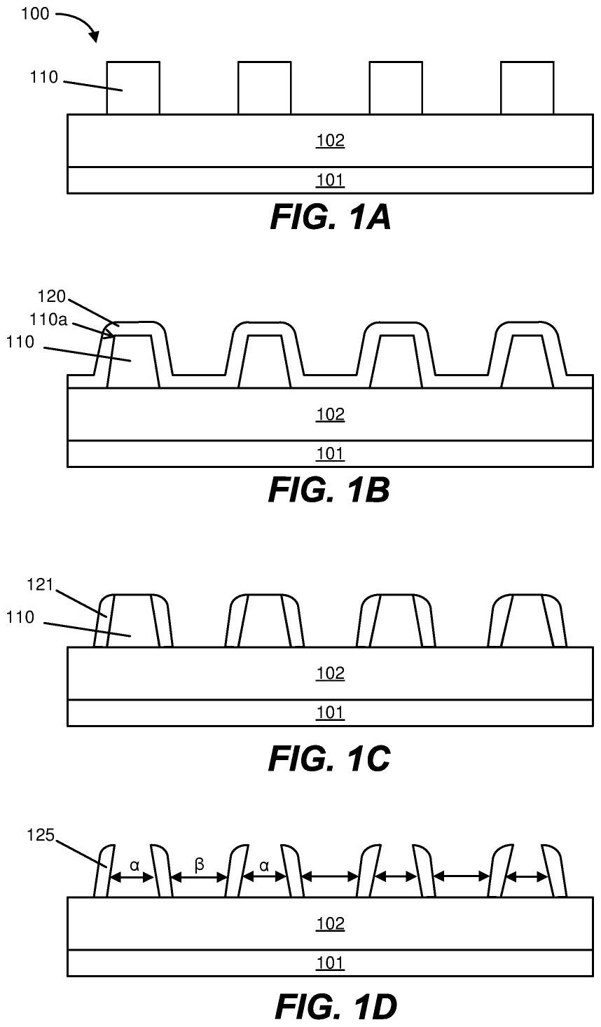

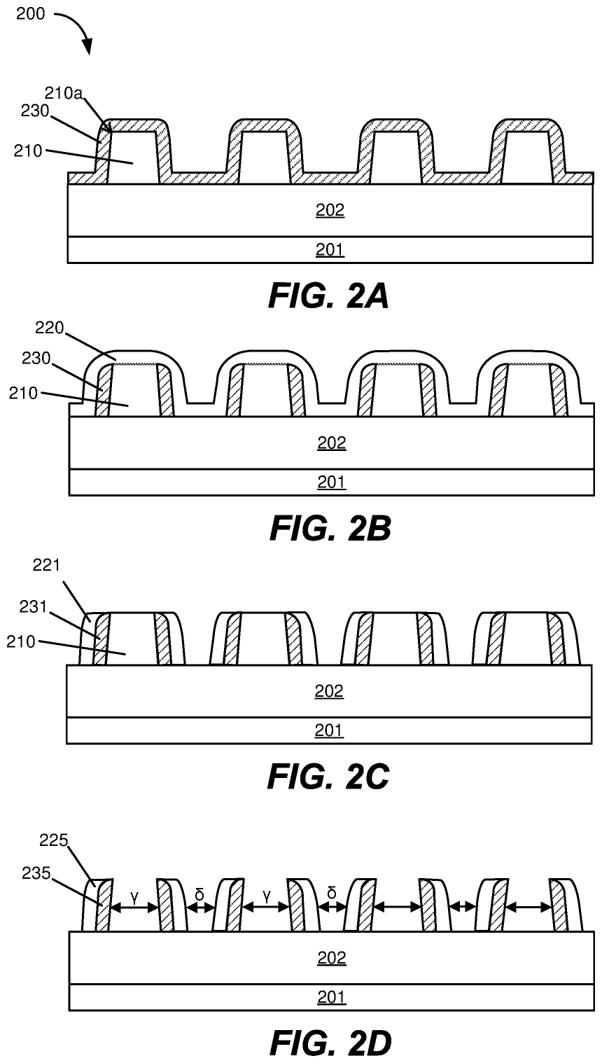

FIGS. 1A-1D and 2A-2D are example schematic illustrations of a substrate in a multiple patterning scheme. FIGS. 1A-1D show an embodiment of patterning which may be a double patterning scheme. In some cases, these substrates may be previously patterned by a first double patterning scheme such that the overall process is a quad patterning scheme. Substrate 100 of FIG. 1A includes mandrels 110, which may be formed by a prior double patterning scheme involving a substrate having a lithographically defined or patterned first core material on a second core material used to later form mandrel 110, and the lithographically defined or patterned first core material may be a photoresist or may include amorphous carbon or amorphous silicon material. The patterned first core may be deposited over the second core material by any suitable deposition technique, such as plasma enhanced chemical vapor deposition (PECVD), and the deposition technique may involve generating a plasma in the deposition chamber from deposition gases including a hydrocarbon precursor. The hydrocarbon precursor may be defined by the formula CₓH_{y}, where x is an integer between 1 and 10, and y is an integer between 2 and 24. Examples include methane (CH₄), acetylene (C₂H₂), ethylene (C₂H₄), propylene (C₃H₆), butane (C₄H₁₀), cyclohexane (C₆H₁₂), benzene (C₆H₆), and toluene (C₇H₈). A dual radio frequency (RF) plasma source including a high frequency (HF) power and a low frequency (LF) power may be used. A double patterning scheme may be used to etch the second core material to form mandrels 110. The patterned second core material may be an amorphous carbon layer, amorphous silicon layer, or a photoresist, such as poly(methyl methacrylate) or poly(methyl glutarimide) (PMGI) or phenol formaldehyde resin.

FIG. 1A shows mandrels 110 over an etch stop layer 102 on a target layer 101. In FIG. 1B, a conformal film 120 is deposited over the mandrels 110. The conformal film 120 may be a dielectric material deposited by atomic layer deposition (ALD) or PEALD. For example, in some embodiments, the conformal film 120 may be silicon oxide. When the conformal film 120 is deposited using oxygen-containing reactants and oxygen-containing plasma, particularly at high plasma power, the mandrels 110 are susceptible to etching when the substrate undergoes process conditions for depositing robust, high modulus materials for the conformal film 120, which results in tapered sidewalls and reduced corners 110a, such that the conformal film 120 has slanted, instead of vertical, sidewalls as shown in FIG. 1B. For example, high modulus dielectric material may involve high radio frequency (RF) energy during deposition, but when the mandrels 110 are exposed to high RF energy, they are susceptible to severe damage, particularly at or near the top of the mandrel. This can result in spacer collapse post etch. In FIG. 1C, the conformal film 120 is directionally etched to form spacers 121 flanking the mandrels 110. In FIG. 1D, the mandrels 110 are selectively removed to leave free-standing spacers 125. Selective removal or selective etching as used herein is defined as etching one material selective to another. It will be understood that in some embodiments, if a first material is etched selective to a second material, the etch rate of the first material is faster than the etch rate of the second material such that for a given duration, more of the first material is etched than the second material. Because the corners 110a of the mandrels 110 were damaged during deposition of the conformal film 120, the free-standing spacers 125 are leaning, and transfer to underlayers such as to target layer 101 will result in varied critical dimensions α and β, which may all be different values. The asymmetry of the free-standing spacers 125 results in uneven etching of the target layer thereby resulting in pitch walking. Etching of the target layer 101 using the asymmetrical free-standing spacers 125 results in ion angular distribution of the etching species that causes angled etching of the target layer. The process results in pitch walking in part because the dry etch conditions during removal of the mandrel results in a shadowing effect.

Provided herein are methods and apparatuses for forming dielectric material, such as forming symmetrical spacers for multiple patterning, by depositing a sacrificial layer on a mandrel or other surface prior to depositing the dielectric material such that the sacrificial layer is capable of being consumed during conformal film deposition of the dielectric material while protecting the mandrels or other surface from damage, by incorporating a soft atomic layer deposition (ALD) process that both deposits material using mild process conditions during conversion of the ALD process to protect the mandrels or other surface from damage and treats the material using a high plasma to densify the film thereafter, and combinations thereof “Soft ALD” as used herein refers to an ALD process where during conversion, low plasma power of less than about 500 W for 4-wafers is used. In some embodiments, treating using high plasma is performed periodically. In some embodiments, treating is performed after every n cycles of ALD, where n is an integer equal to or greater than 1. In some embodiments, treating is performed after a certain number of cycles of ALD in an overall process involving many ALD cycles such as after the mth cycle, m being any integer greater than or equal to 1. In some cases, high plasma ALD may be used after soft ALD.

Methods are suitable for depositing spacer material or dielectric material on a variety of substrate surfaces, including but not limited to nitrides, photoresists, spin-on carbon, PECVD carbon, germanium antimony tellurium, chalcoxides, and combinations thereof. Methods are suitable for processes used to form a variety of structures such as but not limited to double patterning processes, liner deposition processes, contact liner deposition processes, shallow trench isolation, slit fill, and more. Methods can be combined with a variety of both low and high temperature processes.

Sacrificial layers are used in various disclosed embodiments. There exists a correlation between the spacer material deposition process (including the plasma conditions and thickness of the spacer material to be used) and the consumption rate of the sacrificial layer. Such process conditions can be used to determine the amount of sacrificial layer to be deposited to protect the underlying mandrel. Additionally, if both a sacrificial layer and soft ALD are used together, the amount of sacrificial layer to be deposited may be reduced or modified to accommodate the amount of soft ALD that will be deposited. For example, in some embodiments, a thinner sacrificial layer may be used prior to performing soft ALD to form initial layers of a spacer material that consume the thinner sacrificial layer but not the mandrel or other surface underlying the spacer material, followed by performing non-soft ALD over the soft ALD layers. Using certain disclosed embodiments allows formation of a spacer material or other dielectric on a mandrel or other surface without consuming the mandrel or other surface.

Sacrificial layers can be deposited in situ. In various embodiments, sacrificial layers are deposited before depositing any spacer material without breaking vacuum between the two operations. In some embodiments, sacrificial layers are deposited in the same station or the same chamber as the station or chamber used to deposit the spacer material.

Soft ALD processes can be deposited in situ. In some embodiments, deposition of the sacrificial layer, deposition of the spacer material using soft ALD (and optionally with another ALD or chemical vapor deposition (CVD) or other deposition process after a few cycles of soft ALD) can be performed without breaking vacuum. In some embodiments, one or more operations are performed without breaking vacuum. In some embodiments, one or more operations are performed in the same station, or in the same chamber, or in the same tool.

Sacrificial layers can be used to fabricate spacers that are robust because the sacrificial layers protect the mandrel from being consumed during spacer material deposition, thereby allowing the spacer material to be conformally deposited onto a mandrel using high plasma conditions and/or harsh process conditions that may typically damage an unprotected mandrel without damaging the mandrel, and yielding non-leaning spacers on sidewalls of the mandrel. Once the mandrels are removed, these spacers are robust spacers that can be used as a mask for etching subsequent layers. Such spacers may also be symmetrical. Symmetrical spacers are formed by maintaining symmetrical mandrels when spacer material is deposited. Symmetrical spacers provide an improved top profile such that use of the spacer as a mask to etch a target layer does not result in and/or reduces pitch walking. Symmetrical spacers include sharp corners that meet at a point that is about 90°+5°. Disclosed embodiments form spacers having sidewalls perpendicular to or substantially perpendicular to the top surface of the spacer. Substantially perpendicular is defined herein as having an angle of 90°+5°.

Methods involve depositing a sacrificial layer on the mandrel prior to depositing spacer material, depositing spacer material using soft ALD which includes ALD using mild plasma conditions followed by periodic plasma treatment using high plasma conditions to densify the film deposited using mild plasma conditions, and combinations thereof.

Methods involve depositing a sacrificial layer on exposed surfaces of a mandrel using various methods such as chemical vapor deposition (CVD), or ALD, or PEALD, or any other suitable method. The sacrificial layer may be nonconformal in some embodiments. The sacrificial layer may be conformal in some embodiments. The sacrificial layer has properties such that when exposed to deposition reactants for depositing a robust spacer material on the mandrel, the sacrificial layer is selectively removed while protecting the sidewalls and corners of the mandrel and spacer material is grown on exposed surfaces of the mandrel without damaging the sidewalls and corners during deposition. Symmetrical is defined herein as having substantially the same shape on either side. Symmetrical spacers have the same shape on either side after removing the mandrel. For example, symmetrical spacers may have a planar top profile with the vertical surfaces of the spacers oriented at or about 90° from the top horizontal surface of the spacer.

Methods involve depositing one or more cycles of soft ALD material on exposed surfaces of a mandrel using low plasma during conversion of the ALD cycle followed by plasma treatment to improve the quality of the deposited film from each ALD cycle. Plasma treatment may be performed after the mth ALD cycle in a sequence of multiple ALD cycles, where m is an integer greater than or equal to 1. Plasma treatment may be performed between every ALD cycle, or every n ALD cycles, where n is an integer greater than or equal to 1. In some embodiments, n is about 10. Methods involve combining soft ALD with a sacrificial layer; for example, in some embodiments, a thinner sacrificial layer may be deposited, followed by depositing soft ALD material that both consumes the sacrificial layer while protecting the mandrel and deposits high quality spacer material on the mandrel. In some embodiments, depositing the soft ALD material is combined with depositing high quality ALD material. For example, after several cycles of soft ALD, ALD may be performed with high plasma power during conversion with or without plasma treatment when sufficient layers of soft ALD exist on the mandrel to protect it from subsequent deposition conditions.

FIGS. 2A-2D show example schematic illustrations whereby the damage to corners of the mandrels can be mitigated by depositing a soft ALD material in combination with depositing a robust spacer material, which have heterogenous film structures, over the soft landing material. Non-treated soft ALD material used herein refers to material deposited by low process condition ALD prior to plasma treatment. Soft ALD material refers to material deposited by low process condition ALD that has been treated with plasma treatment after every one or more cycles of low process condition ALD.

FIG. 2A shows substrate 200 with target layer 201 and etch stop layer 202 with mandrels 210 atop the etch stop layer 202, with soft ALD material 230 deposited conformally over the mandrels 210. Soft ALD can be performed by depositing material at low process conditions (e.g., low temperature and/or low plasma and/or low exposure time during conversion) followed by plasma treatment every few cycles, such as every about 10 cycles. Damage to corners 210a is reduced or mitigated compared to that of FIG. 1B.

In FIG. 2B, after the soft ALD material 230 is etched to leave soft ALD material 230 on the sidewalls of the mandrels 210, conformal film 220 is deposited over the soft ALD material 230 and the mandrels 210, but because the film is conformal, the film also has sloped or slanted sidewalls. The sloped sidewalls can be mitigated by performing the plasma treatment every few cycles of soft ALD so as not to damage the corners of the mandrel 210.

In FIG. 2C, the horizontal regions of conformal film 220 are selectively removed to result in spacers 221.

In FIG. 2D, mandrels 210 are selectively removed to result in spacer materials that include both soft ALD material 235 and spacer material 225. Although the example shows some leaning in the resulting spacers, leaning can be further reduced by optimizing the plasma treatment conditions between soft ALD cycles and by determining the optimal plasma penetration for treating soft ALD layers so as to perform plasma treatment on sufficiently thin soft ALD layers to convert non-treated soft ALD layers to robust spacer material. The resulting pattern has some varied critical dimensions γ and δ, which may both also be different values; as plasma treatment is optimized, the critical dimensions approach one another to result in reduced pitch walking. Plasma treatment improves the modulus of the non-treated soft ALD material. Without the plasma treatment, the resulting spacers would be less robust and may have lower modulus, resulting in likely collapse and potential damage during subsequent etching processes. Additionally, the heterogeneous nature of the film structure has two types of materials on either side of the spacer, each of which may have different modulus, stress, and etch rate, which can ultimately result in spacer leaning and asymmetrical transfer etching to subsequent layers. Plasma treatment conditions are modulated to accommodate the plasma penetration depth such that plasma treatment can fully convert non-treated soft ALD material to robust ALD material for the spacer, thereby having modulus, stress, and etch rate more similar to that of spacer material deposited using harsher process conditions such as high plasma energy (power and duration).

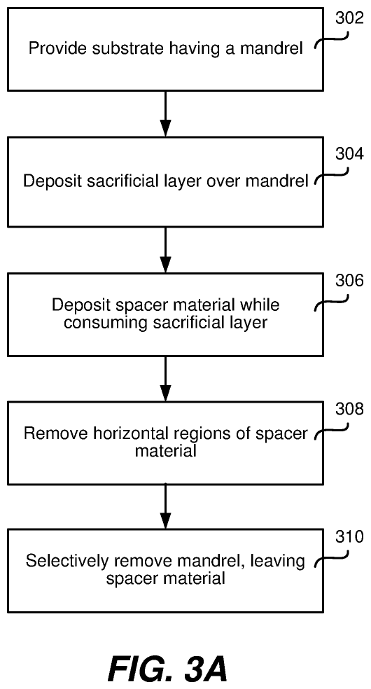

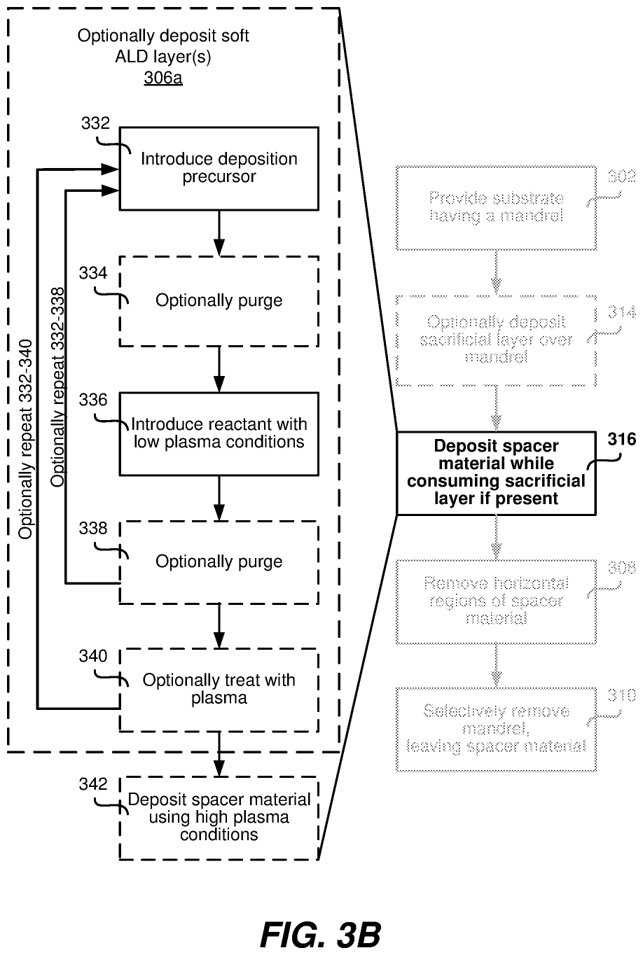

FIG. 3A shows a process flow diagram depicting operations that may be performed in accordance with certain disclosed embodiments. One or more of the operations of FIG. 3A may be performed in various embodiments. In some embodiments, only one of the operations described in FIG. 3A is performed. For example, in some embodiments, a substrate is provided having a mandrel and operation 304 is performed to deposit a sacrificial layer over the mandrel. In another example, a substrate is provided and only operation 306 is performed to deposit spacer material while consuming the sacrificial layer already deposited on mandrels on a substrate. In another example, a substrate is provided and operation 308 is performed to remove horizontal regions of the spacer material. In another example, a substrate is provided and operation 310 is performed to selectively remove the mandrel to form symmetrical spacers. It will be understood that these and other embodiments may be performed using any one or more of the operations described with respect to FIG. 3A.

In operation 302, a substrate having a mandrel is provided. In various embodiments, one or more mandrels are present on the substrate. In some embodiments, mandrels may be patterned core material. The mandrel may be a carbon-containing or silicon-containing material in various embodiments. In some embodiments, the mandrel is a photoresist or may be made of amorphous carbon material or amorphous silicon material. In some embodiments, the mandrel may be transparent. The mandrel is formed by depositing a mandrel material using a deposition technique, such as PECVD. For example, the deposition technique may involve generating a plasma in a deposition chamber housing the substrate from deposition gases including a hydrocarbon precursor. The deposition of the mandrel may be the same as or similar to deposition of the mandrel as described above with respect to FIG. 1A.

In some embodiments, the mandrel material is deposited by spin-on methods. In some embodiments, the mandrel material is spin-on carbon. The mandrel material may be deposited over a target layer prior to being patterned to form mandrels. The target layer may be the layer ultimately to be patterned by a mask. The target layer may be a semiconductor, dielectric, or other layer and may be made of silicon (Si), silicon oxide (SiO₂), silicon nitride (SiN), or titanium nitride (TiN), for example. The target layer may be deposited by ALD, PEALD, CVD, or another suitable deposition technique. In some embodiments, one or more additional layers may be between the mandrel material and the target layer, including but not limited to an etch stop layer. The mandrel material may be etched, such as by lithography, by thermal etching, by plasma etching, or another etching technique, to form mandrels having a pitch. In some embodiments, the pitch may be about 35 nm to about 100 nm. The critical dimension of the mandrels may be about 12 nm to about 40 nm. Mandrels may have horizontal surfaces at the top of the mandrels with substantially vertical sidewalls. The depth of mandrels or the vertical length of sidewalls may be about 50 nm to about 90 nm. Gaps between mandrels may have an aspect ratio of about 1.1 to about 4.0.

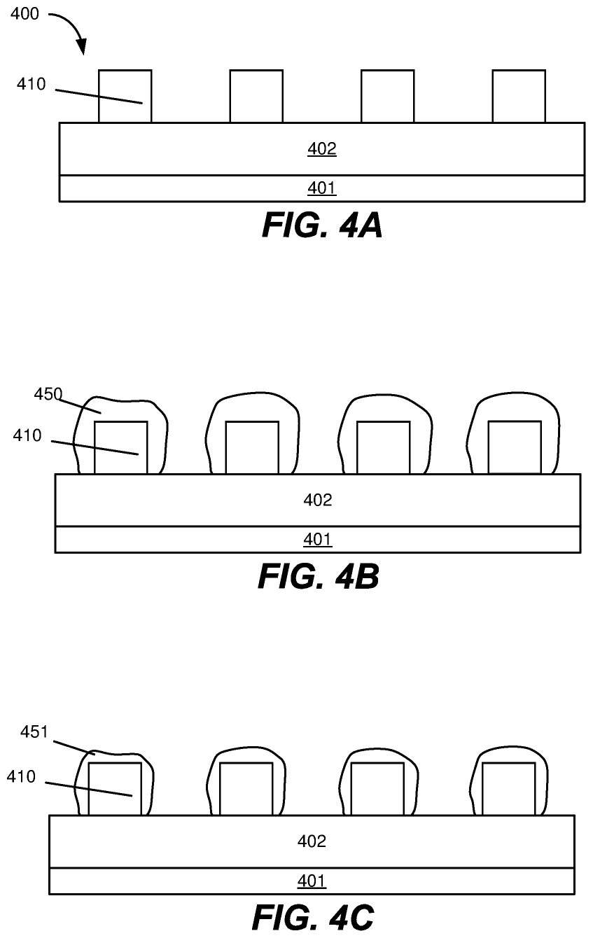

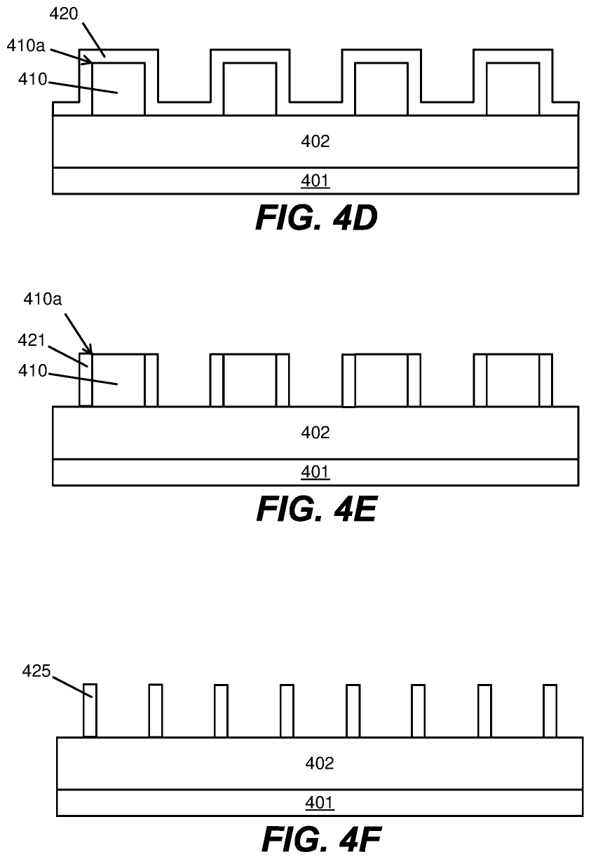

FIG. 4A shows an example substrate 400 having mandrels 410 on an etch stop layer 402 over a target layer 401. The mandrels 410 may be any material such as that described with respect to operation 302. The etch stop layer 402 may be a dielectric material or an anti-reflective layer (such as a silicon-containing anti-reflective coating (SiARC) or bottom anti-reflective coating (BARC) or nitrogen-free anti-reflective layer (NFARL)) in some embodiments. The target layer 401 may be a semiconductor material.

Returning to FIG. 3A, in operation 304, a sacrificial layer is deposited over the mandrel. In some embodiments, the sacrificial layer is deposited on the mandrel. In some embodiments, the sacrificial layer is deposited directly on the mandrel. In some embodiments, the sacrificial layer is deposited directly on the mandrel without an intervening layer between the sacrificial layer and the mandrel. In some embodiments, the mandrel is exposed to deposition reactants and conditions to form a sacrificial layer on exposed regions of the mandrel. Exposed regions of the mandrel may include sidewalls of the mandrel and the top of the mandrel. Exposed regions of the mandrel may include a horizontal top region of the mandrel. Exposed regions of the mandrel may also include corners of the mandrel at or near the openings of gaps between mandrels.

The sacrificial layer may be amorphous in some embodiments. In various embodiments, the sacrificial layer is a carbon-containing material. In various embodiments, the sacrificial layer is deposited by spin-on methods. In some embodiments, the sacrificial layer is amorphous carbon. In some embodiments, the sacrificial layer is spin-on carbon. In some embodiments, the sacrificial layer is diamond-like carbon. In various embodiments, the sacrificial layer is deposited by CVD. In various embodiments, the sacrificial layer is deposited by PECVD. In various embodiments, the sacrificial layer is deposited by ALD. In some embodiments, the sacrificial layer is deposited using a carbon-containing precursor. In some embodiments, the carbon-containing precursor is an alkane. In some embodiments, the carbon-containing precursor is a gaseous alkane. Example alkanes include methane, ethane, propane, butane, pentane, hexane, heptane, octane, and the like. In some embodiments, the carbon-containing precursor is methane. In some embodiments, the carbon-containing precursor is an alkene. In some embodiments, the carbon-containing precursor is an alkyne. In some embodiments, the carbon-containing precursor is acetylene. The carbon-containing precursor selected to deposit the sacrificial layer may be a material compatible with sharing tubing with oxidizing chemistries and/or silicon oxide deposition precursors.

In some embodiments, the sacrificial layer has a density less than density of the mandrel. In some embodiments, the sacrificial layer has a modulus less than that of the mandrel. In some embodiments, the sacrificial layer is deposited to a thickness than is sufficiently thin so as to deposit none or less than about 5 Å or less than about 1 Å or less than about 0.5 Å sacrificial layer material at or near the corner where the mandrel meets the etch stop layer.

Temperature is correlated to the quality and susceptibility of the sacrificial layer to being more quickly consumed during deposition of a spacer layer material. In some embodiments, when lower temperature is used during deposition of the sacrificial layer, a thicker sacrificial layer may be deposited because the quality of the sacrificial layer is reduced, so it is more likely to deteriorate faster when exposed to deposition conditions of a later operation for depositing spacer material. A thicker layer can withstand later deposition conditions of the spacer layer material. Lower temperatures may include less than about 50° C. or about 25° C. to about 50° C. A “thicker sacrificial layer” may be a sacrificial layer having a thickness of greater than about 3 nm of material

In some embodiments, when higher temperature is used during deposition of the sacrificial layer, a thinner sacrificial layer may be deposited. Using higher temperature results in a higher quality sacrificial layer, which is less likely to deteriorate quickly when exposed to deposition conditions of a later operation for depositing spacer material. A thinner layer can still withstand later deposition conditions because the higher temperature used helped form a more robust sacrificial layer. Higher temperatures may include greater than about 50° C. or about 50° C. to about 120° C. A “thinner sacrificial layer” may be a sacrificial layer having a thickness of less than about 1 nm of material.

FIG. 4B shows sacrificial layer 450 deposited on the mandrel 410. As shown, sacrificial layer 450 may not necessarily be conformal. In some embodiments, the sacrificial layer 450 may be conformal. Conformality of films may be measured by the step coverage. One example of step coverage may be calculated by dividing the average thickness of the deposited film on the sidewall by the average thickness of the deposited film at the top of the feature and multiplying it by 100 to obtain a percentage. Step coverage may be calculated by comparing the average thickness of a deposited film on a bottom, sidewall, or top of a feature to the average thickness of a deposited film on a bottom, sidewall, or top of a feature. A “feature” of a substrate may be a mandrel (a positive feature) or a via or contact hole (a negative feature), which may be characterized by one or more of narrow and/or re-entrant openings, constrictions within the feature, and a high aspect ratio. The step coverage of sacrificial layer 450 on mandrel 410 may be at least about 50% or at least about 60% or about 80%.

The step coverage and uniformity of film property along the sidewall depends on, among many factors, the transport of the deposition precursor, reactant ions and/or radicals (such as those generated by igniting a reactant gas with a plasma), and byproducts. As the dimension of the gap between mandrels is reduced from deposition of the sacrificial layer, the transport becomes increasing difficult in the gaps which may result in more deposition of the sacrificial layer in the top about 50% of the sidewalls of the mandrel and the top horizontal regions of the mandrel as compared to the bottom about 50% of the sidewalls of the mandrel and the bottom region on the exposed region of the etch stop layer. In some embodiments, no sacrificial layer material is deposited on the etch stop layer. In some embodiments, little sacrificial layer material (such as less than about 1 nm of material) is deposited on the etch stop layer.

In various embodiments, the sacrificial layer 450 deposits preferentially on the mandrels 410 and not on etch stop layer 402. In some embodiments, the sacrificial layer 450 deposits more sacrificial layer material at or near the top of the mandrels 410, such as at corners of the mandrels 410, or on the top horizontal surface of the mandrels 410, or at the top about 10% to about 40% of the sidewalls of the mandrels 410.

The thickness of the sacrificial layer 450 deposited on the mandrel 410 depends on the chemistry used to deposit and the thickness deposited of the spacer material in operation 306 of FIG. 3A which is further described below. In various embodiments, the thickness of the sacrificial layer 450 may reduce the size of openings in gaps between mandrels 410 from before depositing the sacrificial layer 450 to about 80% or less of the size of openings before depositing the sacrificial layer 450. For example, an opening of 100 nm between mandrels 410 before depositing the sacrificial layer 450 may be reduced to an opening of about 80 nm or less after depositing the sacrificial layer 450. The sacrificial layer 450 is deposited so as not to close the gap between mandrels 410. In some embodiments, the sacrificial layer 450 is deposited leaving a gap of about 5 nm to about 10 nm or greater between adjacent exposed surfaces of sacrificial layer 450.

Returning to FIG. 3A, in operation 306, a spacer material is deposited. FIG. 3B shows a process flow diagram depicting operations that may be performed in accordance with certain disclosed embodiments where soft ALD is performed. As shown in FIG. 3B, in some embodiments, operation 304 in FIG. 3A for depositing the sacrificial layer is optional as operation 314 to optionally deposit a sacrificial layer over the mandrel. One or more of the operations of FIG. 3B may be performed in various embodiments.

In some embodiments, regardless of whether a sacrificial layer is previously deposited, a spacer material may be deposited in operation 316. If a sacrificial layer was optionally deposited in operation 314, the spacer material is deposited while consuming the sacrificial layer in operation 316. The spacer material may involve optionally depositing soft ALD material per operation 306a, which may include operations 332-338, and optionally 340 for optionally treating with a plasma. In some embodiments, the spacer material is deposited using only operation 342 for depositing spacer material using high plasma conditions. In some embodiments, the spacer material is deposited using operations 306a and operation 342. In some embodiments, the spacer material is deposited in accordance with operation 306 as noted above with respect to FIG. 3A.

In embodiments where the sacrificial layer is deposited over the mandrel in operation 304, the spacer material is deposited while consuming the sacrificial layer. The sacrificial layer acts as a barrier between the chemistries used to deposit the spacer material and the mandrel to reduce and/or eliminate damage on the mandrel. Deposition of the spacer material includes exposing the sacrificial layer to an oxidant.

The spacer material is deposited using CVD, PECVD, ALD, or another suitable technique. ALD is a technique that deposits thin layers of material using sequential self-limiting reactions. ALD processes use surface-mediated deposition reactions to deposit films on a layer-by-layer basis in cycles. As an example, an ALD cycle may include the following operations: (i) delivery/adsorption of a precursor, (ii) purging of the precursor from the chamber, (iii) delivery of a second reactant and optionally ignite plasma, and (iv) purging of byproducts from the chamber. The reaction between the second reactant and the adsorbed precursor to form a film on the surface of a substrate affects the film composition and properties, such as nonuniformity, stress, wet etch rate, dry etch rate, electrical properties (e.g., breakdown voltage and leakage current), etc.

In one example of an ALD process, a substrate surface that includes a population of surface active sites is exposed to a gas phase distribution of a first precursor, such as a silicon-containing precursor, in a dose provided to a chamber housing the substrate. Molecules of this first precursor are adsorbed onto the substrate surface, including chemisorbed species and/or physisorbed molecules of the first precursor. It should be understood that when a compound is adsorbed onto the substrate surface as described herein, the adsorbed layer may include the compound as well as derivatives of the compound. For example, an adsorbed layer of a silicon-containing precursor may include the silicon-containing precursor as well as derivatives of the silicon-containing precursor. After a first precursor dose, the chamber is then evacuated to remove most or all of first precursor remaining in gas phase so that mostly or only the adsorbed species remain. In some implementations, the chamber may not be fully evacuated. For example, the reactor may be evacuated such that the partial pressure of the first precursor in gas phase is sufficiently low to mitigate a reaction. A second reactant, such as an oxygen-containing gas, is introduced to the chamber so that some of these molecules react with the first precursor adsorbed on the surface. In some processes, the second reactant reacts immediately with the adsorbed first precursor. In other embodiments, the second reactant reacts only after a source of activation such as plasma is applied temporally. The chamber may then be evacuated again to remove unbound second reactant molecules. As described above, in some embodiments the chamber may not be completely evacuated. Additional ALD cycles may be used to build film thickness.

In some implementations, the ALD methods include plasma activation. As described herein, the ALD methods and apparatuses described herein may be conformal film deposition (CFD) methods, which are described generally in U.S. patent application Ser. No. 13/084,399 (now U.S. Pat. No. 8,728,956), filed Apr. 11, 2011, and titled “PLASMA ACTIVATED CONFORMAL FILM DEPOSITION,” and in U.S. patent application Ser. No. 13/084,305, filed Apr. 11, 2011, and titled “SILICON NITRIDE FILMS AND METHODS,” which are herein incorporated by reference in their entireties.

In optional operation 306a, a deposition precursor is introduced in operation 332. The deposition precursor depends on the spacer material to be deposited. In some embodiments, the deposition precursor is an silicon-containing precursor.

In operation 306, deposition of spacer material using ALD may involve exposing the sacrificial layer to a silicon-containing precursor.

A silicon-containing precursor is introduced to adsorb the silicon-containing precursor onto the substrate surface. Silicon-containing precursors suitable for use in accordance with disclosed embodiments include polysilanes (H₃Si—(SiH₂)ₙ—SiH₃), where n>0, halosilanes, aminosilanes, siloxanes, and any other precursor having silicon atoms. Examples of silanes are silane (SiH₄), disilane (Si₂H₆), and organosilanes such as methylsilane, ethylsilane, isopropylsilane, t-butylsilane, dimethylsilane, diethylsilane, di-t-butylsilane, allylsilane, sec-butylsilane, thexylsilane, isoamylsilane, t-butyldisilane, di-t-butyldisilane, and the like.

A halosilane includes at least one halogen group and may or may not include hydrogens and/or carbon groups. Examples of halosilanes are iodosilanes, bromosilanes, chlorosilanes, and fluorosilanes. Although halosilanes, particularly fluorosilanes, may form reactive halide species that can etch silicon materials when a plasma is struck, a halosilane may not be introduced to the chamber when a plasma is struck in some embodiments, so formation of a reactive halide species from a halosilane may be mitigated. Specific chlorosilanes are tetrachlorosilane, trichlorosilane, dichlorosilane, monochlorosilane, chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, thexyldimethylchlorosilane, and the like.

An aminosilane includes at least one nitrogen atom bonded to a silicon atom, but may also contain hydrogens, oxygens, halogens, and carbons. Examples of aminosilanes are mono-, di-, tri- and tetra-aminosilane (H₃Si(NH₂), H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, tert-butylsilanamine, bis(tert-butylamino)silane (SiH₂(NHC(CH₃)₃)₂ (BTBAS), tert-butyl silylcarbamate, SiH(CH₃)—(N(CH₃)₂)₂, SiHCl—(N(CH₃)₂)₂, (Si(CH₃)₂NH)₃₊, diisopropyl aminosilane (DIPAS), di-sec-butylaminosilane (DSBAS), bis(diethylamino)silane (BDEAS) (SiH₂[N(CH₂CH₃)₂]₂), and the like. A further example of an aminosilane is trisilylamine (N(SiH₃)).

For an ALD process, deposition may also include exposure to an oxygen source, such as oxygen, nitrous oxide, carbon dioxide, peroxide, ozone, nitric oxide, or other oxygen-containing gases or combinations thereof. In some embodiments, the oxygen source is a gas. The oxygen source may be diluted with an inert gas or introduced with an inert gas, such as argon, helium, hydrogen, or nitrogen. Process gas flow rates may be as follows: for (liquid) silicon precursor (e.g., BTBAS, BDEAS, and DIPAS), between about 1 sccm and 3 sccm, for example BTBAS at about 2.5 sccm; for oxygen precursor (O₂, N₂O), between about 5000 sccm and 10,000 sccm, for example N₂O at 5000 sccm; and for the carrier gas (Ar or N₂), between about 0 sccm and 10,000 sccm, for example about 5000 sccm Ar.

The process chamber housing the substrate may be optionally purged in operation 334 to remove precursors that are not adsorbed onto the substrate surface. Purging the chamber may involve flowing a purge gas or a sweep gas, which may be a carrier gas used in other operations or may be a different gas. Example purge gases include argon, nitrogen, hydrogen, and helium. In various embodiments, the purge gas is an inert gas. Example inert gases include argon, nitrogen, and helium. In some embodiments, purging may involve evacuating the chamber. In some embodiments, operation 305 may include one or more evacuation subphases for evacuating the process chamber. Alternatively, it will be appreciated that purging may be omitted in some embodiments. Purging may have any suitable duration, such as between about 0.1 seconds and about 2 seconds.

In operation 336, the substrate is exposed to an oxidant and a plasma is ignited under low plasma conditions to convert the adsorbed precursors to conformal spacer material. For example, in various embodiments, a conformal silicon oxide spacer material is formed over the substrate. Where silicon oxide spacer is being deposited, the silicon-containing precursor adsorbed onto the substrate surface reacts with the oxidizing plasma to form silicon oxide. Example oxidants include oxygen gas, water, carbon dioxide, nitrous oxide, and combinations thereof. In various embodiments, the substrate is exposed to an oxidant and an inert gas simultaneously while the plasma is ignited. For example, in one embodiment, a mixture of oxygen and argon is introduced to the substrate while the plasma is ignited.

Plasma energy is provided to activate the second reactant, such as an oxygen-containing gas or oxidant, into ions and radicals and other activated species, which react with the adsorbed layer of the first precursor. For example, the plasma may directly or indirectly activate the oxygen-containing gas phase molecules to form oxygen radicals or ions.

The substrate including the adsorbed layer of silicon-containing precursor is exposed to an oxidant and a plasma is ignited under conditions to convert the adsorbed precursors to silicon oxide using the oxidizing plasma. Example oxidants include oxygen gas, water, carbon dioxide, nitrous oxide, and combinations thereof. In various embodiments, the substrate is exposed to an oxidant and an inert gas simultaneously while the plasma is ignited. For example, in one embodiment, a mixture of oxygen and argon is introduced to the substrate while the plasma is ignited. The chamber may then be purged again to remove unreacted oxidant and/or byproducts from the reaction for forming silicon oxide. These dose, purge, conversion, purge operations may be repeated in multiple cycles to deposit spacer material layer by layer conformally over the substrate. For example, deposition cycles of ALD may be repeated for a number of cycles such that the distance in the space between the film deposited on the sidewalls is between about 5 nm and about 50 nm.

The plasma may be ignited using radio frequency (RF) power. The RF power for four stations may be about 500 W may be considered low, and may form spacer material that is less robust so as not to damage the underlying substrate. RF activation frequency can vary from about 13.56 MHz to 40 MHz for various embodiments. An non-treated soft ALD material may be deposited using a plasma power of about 100 W to about 500 W for a 4-station chamber for a duration of about 0.05 seconds to about 0.25 seconds during conversion.

Deposition may occur at a temperature of about 20° C. to about 400° C., or about 20° C. to about 30° C., or about 25° C. Deposition may be performed at a chamber pressure of about 0.5 Torr to about 10 Torr. The amount of material deposited using repeated ALD cycles to form a non-treated soft ALD material may be about 10 Å to about 20 Å, or greater.

If a sacrificial layer is used, overall exposure time to deposition chemistries to deposit the spacer material depends on the material of the sacrificial layer, thickness of the sacrificial layer, the etch rate of the sacrificial layer, and the etch chemistries used. In various embodiments, after milliseconds or seconds of exposure to the oxidizing plasma, the sacrificial layer is etched or consumed. In some embodiments, the plasma is exposed for a duration of about 0.1 to about 5 seconds, or about 0.1 to about 1 second, or about 0.1 to about 0.3 seconds. The amount of mandrel consumed during operation 306 is less than about 5 Å or less than about 1 Å or less than about 0.5 Å or about 0 Å.

In operation 338, the chamber may be optionally purged again to remove deposition byproducts and other excess gases. The purging process gases and conditions may be the same as those described above with respect to operation 334 or may be any one or more of the conditions described above with respect to operation 334.

In operation 340, the substrate is optionally treated with a plasma to convert the non-treated soft ALD material to soft ALD spacer material having robust features such as high density and modulus. In various embodiments, treatment is performed every ALD cycle, or every about 10 cycles, or about every 15 cycles, or about every 20 cycles, or about every 30 cycles, or more. The frequency of plasma treatment as well as the plasma treatment time each time it is used depends on the non-treated soft ALD material deposited including its deposition precursors, deposition conditions, and composition. The plasma penetration depth may be determined by first depositing a thick film and determining wet etch rate and electrical properties to determine the RF budget, and performing experiments using plasma treatment every n cycles, varying n in each experiment, to determine the number of cycles used that results in low leakage with sufficient thickness (that is, where thickness is not substantially increased as compared to depositing non-treated soft ALD). The minimum thickness determined from those experiments can be used to deposit a minimum thickness onto a mandrel at the lower RF budget without damaging the substrate and plasma treatment can be performed at the determined frequency to balance film quality with film thickness. The film is densified during plasma treatment at the RF budget. Plasma penetration or diffusion depth refers to how deep the plasma penetrates into the film surface to densify and/or modulate the properties of the film using oxidizing radicals and ions.

In some embodiments, plasma treatment is performed for a film having a thickness of about 10 Å to about 20 Å at a plasma power of about 2500 W to about 5000 W for a 4-station chamber for a duration of about 5 seconds to about 20 seconds.

In operation 342, spacer material is optionally deposited using high plasma conditions. That is, in some embodiments, operation 340 is used such that soft ALD material is used as the spacer entirely. In some embodiments, operation 342 is performed after depositing a particular thickness of soft ALD material. The thickness of the soft ALD material may be determined such that it is sufficient to protect the mandrel from high plasma or harsher deposition conditions for depositing spacer material in operation 342. In some embodiments, the thickness of the soft ALD material that is deposited before depositing spacer material at harsher process conditions is at least about 10 Å, or at least about 20 Å, or at least about 30 Å, or less than about 1000 Å, or less than about 500 Å, or less than about 200 Å, or less than about 100 Å, or less than about 50 Å, or about 10 Å to about 50 Å.

The high plasma or harsher deposition condition spacer material is deposited using CVD, PECVD, ALD, or another suitable technique. ALD is a technique that deposits thin layers of material using sequential self-limiting reactions. During ALD in operation 342, the plasma may be ignited using radio frequency (RF) power. The RF power for four stations may be about 200 W to about 5 kW. The RF power per substrate area may be about 0.00071 W/mm² to about 0.0177 W/mm², or greater than 0.0007 W/mm², or greater than 0.02 W/mm². The plasma power may be about 3 kW in various embodiments for a 4-station chamber. A plasma power of about 3 kW may be considered high but sufficient to deposit a robust spacer material that has a higher modulus, increased structural stability, and less susceptible to spacer leaning. In some embodiments, plasma powers less than about 500 W may be considered low, and may form spacer material that is less robust, having a lower modulus, and having more susceptibility to spacer leaning. RF activation frequency can vary from about 13.56 MHz to 40 MHz for various embodiments.

The process gases, deposition scheme including deposition precursors and purging operations, discussed above with respect to operations 332-338 may be used to deposit spacer material in operation 342, except that the plasma conditions during conversion of the adsorbed precursor to an oxidant and a plasma is higher than that of the soft ALD layers. Additionally, treating with a plasma after operation 342 may not be necessary.

In some embodiments, operations 332-338 are repeated multiple times, or operations 332-340 are repeated multiple times, or operation 340 is performed every one or more cycles of performing operations 332-338. In some embodiments, after one or more cycles of operations 332-340, operation 342 is performed. In some embodiments, only operation 342 is performed. In some embodiments, operation 314 is performed followed by performing cycles of operations 332-340 and operation 342. In some embodiments, operation 314 is not performed and only cycles of operations 332-340 are performed to form the spacer material. In some embodiments, operation 314 is not performed and operations 332-340 are performed in cycles followed by operation 342. In some embodiments, operation 314 is performed and operations 332-340 are performed but operation 342 is not performed. Any other combination may also be used. In general, operation 314 is typically performed before depositing spacer material in operation 316. Deposition of the spacer material in operation 316 consumes any present sacrificial layer deposited in operation 314.

Returning to FIG. 3A, during operation 306 of FIG. 3A, as sacrificial layer is consumed, exposed regions of the mandrel are exposed to the deposition chemistry for depositing the spacer material (such as silicon-containing precursors for adsorption and an oxidizing plasma to convert the adsorbed silicon-containing precursors to silicon oxide). The presence of the sacrificial layer and etched byproducts of the sacrificial layer may contribute to protecting the mandrel during deposition of the spacer material, resulting in reduced damage on the mandrel.

FIG. 4D shows an example whereby spacer material 420 is deposited conformally onto mandrel 410 with the sacrificial layer 451 from FIG. 4C removed. Corners 410a have been protected and the sidewalls of the mandrel 410 meet the horizontal portion of the mandrel 410 at about a right angle.

Returning to FIG. 3A, in operation 308 of FIG. 3A, top horizontal regions of spacer material are removed. This may be performed using a directional etching process in various embodiments. As shown in FIG. 4E, top horizontal regions of the spacer material 420 are removed to leave free-standing sidewall spacers 421 adjacent to sidewalls of mandrel 410, thereby exposing the top horizontal regions of mandrel 410 and top horizontal regions of etch stop layer 402.

Returning to FIG. 3A, in operation 310, the mandrel is selectively removed, leaving the spacer material that can be used as a mask to etch underlayers. FIG. 4F shows the mandrels 410 from FIG. 4E removed leaving sidewall spacers 425. As shown, the sidewall spacers 425 are not leaning as the mandrels that were selectively removed did not have tapered or leaning sidewalls due to protection of the mandrels during deposition of the spacer material, thereby, allowing sidewall spacers 425 to maintain the desired pitch for use as a mask for etching subsequent layers.

### Apparatus

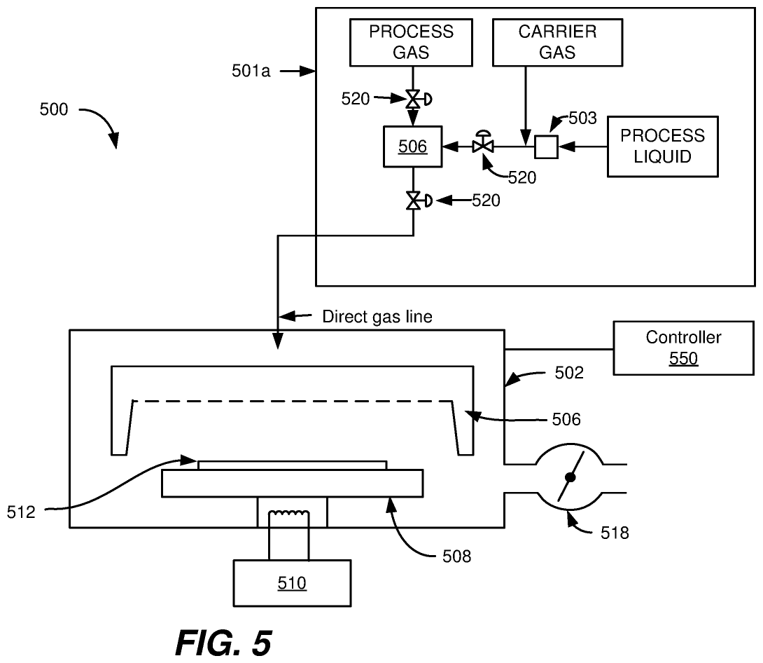

FIG. 5 schematically shows an embodiment of a process station 500 that may be used to deposit material using chemical vapor deposition (CVD) or atomic layer deposition (ALD), which may be plasma enhanced as described above. For simplicity, the process station 500 is depicted as a standalone process station having a process chamber body 502 for maintaining a process environment which in some embodiments may be a low-pressure environment. However, it will be appreciated that a plurality of process stations 500 may be included in a process tool. Further, it will be appreciated that, in some embodiments, one or more hardware parameters of process station 500, including those discussed in detail below, may be adjusted programmatically by one or more computer controllers.

Process station 500 fluidly communicates with reactant delivery system 501 for delivering process gases to a distribution showerhead 506. Reactant delivery system 501 includes a mixing vessel 504 for blending and/or conditioning process gases for delivery to showerhead 506. One or more mixing vessel inlet valves 520 may control introduction of process gases to mixing vessel 504. Similarly, a showerhead inlet valve 505 may control introduction of process gases to the showerhead 506. Processes gases such as carbon-containing gases, silicon-containing gases, oxygen-containing gases, and inert gases may be introduced to the showerhead 506. Example carbon-containing gases include methane and acetylene. Example silicon-containing gases include silanes. Example oxygen-containing gases include oxygen, ozone, nitrous oxide, nitric oxide, carbon dioxide, and peroxides.

In some embodiments, processes gases are stored in gas form and vaporization is not used. Some process gases may be stored in liquid form prior to vaporization at and subsequent delivery to the process station. For example, the embodiment of FIG. 5 includes a vaporization point 503 for vaporizing liquid reactant to be supplied to mixing vessel 504. In some embodiments, vaporization point 503 may be a heated vaporizer. The reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 503 may be heat traced. In some examples, mixing vessel 504 may also be heat traced. In one non-limiting example, piping downstream of vaporization point 503 has an increasing temperature profile extending from approximately 100° C. to approximately 150° C. at mixing vessel 504.

In some embodiments, reactant liquid may be vaporized at a liquid injector. For example, a liquid injector may inject pulses of a liquid reactant into a carrier gas stream upstream of the mixing vessel. In one scenario, a liquid injector may vaporize reactant by flashing the liquid from a higher pressure to a lower pressure. In another scenario, a liquid injector may atomize the liquid into dispersed microdroplets that are subsequently vaporized in a heated delivery pipe. It will be appreciated that smaller droplets may vaporize faster than larger droplets, reducing a delay between liquid injection and complete vaporization. Faster vaporization may reduce a length of piping downstream from vaporization point 503. In one scenario, a liquid injector may be mounted directly to mixing vessel 504. In another scenario, a liquid injector may be mounted directly to showerhead 506.

In some embodiments, a liquid flow controller upstream of vaporization point 503 may be provided for controlling a mass flow of liquid for vaporization and delivery to process station 500. For example, the liquid flow controller (LFC) may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, the LFC may be dynamically switched from a feedback control mode to a direct control mode by disabling a sense tube of the LFC and the PID controller.

Showerhead 506 distributes process gases toward substrate 512. In the embodiment shown in FIG. 5, substrate 512 is located beneath showerhead 506, and is shown resting on a pedestal 508. It will be appreciated that showerhead 506 may have any suitable shape and may have any suitable number and arrangement of ports for distributing processes gases to substrate 512.

In some embodiments, a microvolume 507 is located beneath showerhead 506. Performing an ALD and/or CVD process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle drops, the cycle time also simultaneously reduces. In certain cases, the effect of the latter is dramatic enough to improve overall throughput of the module for a given target thickness of film.

In some embodiments, pedestal 508 may be raised or lowered to expose substrate 512 to microvolume 507 and/or to vary a volume of microvolume 507. For example, in a substrate transfer phase, pedestal 508 may be lowered to allow substrate 512 to be loaded onto pedestal 508. During a deposition process phase, pedestal 508 may be raised to position substrate 512 within microvolume 507. In some embodiments, microvolume 507 may completely enclose substrate 512 as well as a portion of pedestal 508 to create a region of high flow impedance during a deposition process.

In some embodiments, microvolume 507 is not used.

Optionally, pedestal 508 may be lowered and/or raised during portions the deposition process to modulate process pressure, reactant concentration, etc., within microvolume 507. In one scenario where process chamber body 502 remains at a base pressure during the deposition process, lowering pedestal 508 may allow microvolume 507 to be evacuated. Example ratios of microvolume to process chamber volume include, but are not limited to, volume ratios between 1:900 and 1:10. It will be appreciated that, in some embodiments, pedestal height may be adjusted programmatically by a suitable computer controller.

In another scenario, adjusting a height of pedestal 508 may allow a plasma density to be varied during plasma activation and/or treatment cycles included in the deposition process. At the conclusion of the deposition process phase, pedestal 508 may be lowered during another substrate transfer phase to allow removal of substrate 512 from pedestal 508.

While the example microvolume variations described herein refer to a height-adjustable pedestal, it will be appreciated that, in some embodiments, a position of showerhead 506 may be adjusted relative to pedestal 508 to vary a volume of microvolume 507. Further, it will be appreciated that a vertical position of pedestal 508 and/or showerhead 506 may be varied by any suitable mechanism within the scope of the present disclosure. In some embodiments, pedestal 508 may include a rotational axis for rotating an orientation of substrate 512. It will be appreciated that, in some embodiments, one or more of these example adjustments may be performed programmatically by one or more suitable computer controllers.

Returning to the embodiment shown in FIG. 5, showerhead 506 and pedestal 508 electrically communicate with RF power supply 514 and matching network 516 for powering a plasma. In some embodiments, the plasma energy may be controlled by controlling one or more of a process station pressure, a gas concentration, an RF source power, an RF source frequency, and a plasma power pulse timing. For example, RF power supply 514 and matching network 516 may be operated at any suitable power to form a plasma having a desired composition of radical species. Examples of suitable powers are included above. Likewise, RF power supply 514 may provide RF power of any suitable frequency. In some embodiments, RF power supply 514 may be configured to control high- and low-frequency RF power sources independently of one another. Example low-frequency RF frequencies may include, but are not limited to, frequencies between 50 kHz and 900 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert and/or a reactant gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some deposition processes, plasma strikes last on the order of a few seconds or more in duration. In certain implementations, much shorter plasma strikes may be used. These may be on the order of 10 ms to 1 second, typically, about 20 to 80 ms, with 50 ms being a specific example. Such very short RF plasma strikes require extremely quick stabilization of the plasma. To accomplish this, the plasma generator may be configured such that the impedance match is set preset to a particular voltage, while the frequency is allowed to float. Conventionally, high-frequency plasmas are generated at an RF frequency at about 13.56 MHz. In various embodiments disclosed herein, the frequency is allowed to float to a value that is different from this standard value. By permitting the frequency to float while fixing the impedance match to a predetermined voltage, the plasma can stabilize much more quickly, a result which may be important when using the very short plasma strikes associated with some types of deposition cycles.

In some embodiments, pedestal 508 may be temperature controlled via heater 510. Further, in some embodiments, pressure control for deposition process station 500 may be provided by butterfly valve 518. As shown in the embodiment of FIG. 5, butterfly valve 518 throttles a vacuum provided by a downstream vacuum pump (not shown). However, in some embodiments, pressure control of process station 500 may also be adjusted by varying a flow rate of one or more gases introduced to process station 500.

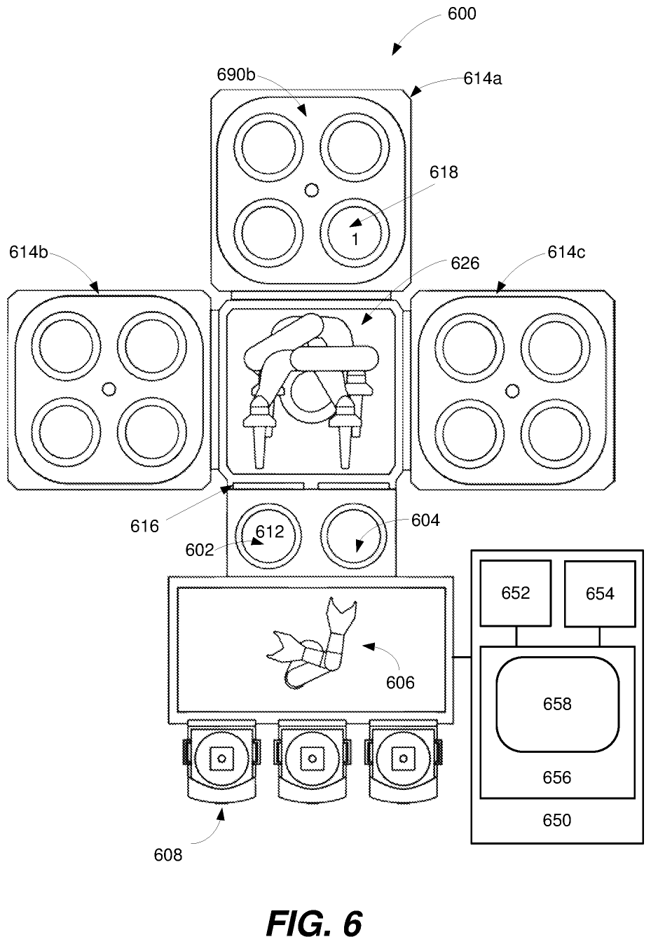

As described above, one or more process stations may be included in a multi-station processing tool. FIG. 6 shows a schematic view of an embodiment of a multi-station processing tool 600 with an inbound load lock 602 and an outbound load lock 604, either or both of which may comprise a remote plasma source. A robot 606, at atmospheric pressure, is configured to move substrates or wafers from a cassette loaded through a pod 608 into inbound load lock 602 via an atmospheric port 610. A substrate is placed by the robot 606 on a pedestal 612 in the inbound load lock 602, the atmospheric port 610 is closed, and the load lock is pumped down. Where the inbound load lock 602 comprises a remote plasma source, the substrate may be exposed to a remote plasma treatment in the load lock prior to being introduced into a processing chamber 614. Further, the substrate also may be heated in the inbound load lock 602 as well, for example, to remove moisture and adsorbed gases. Next, a chamber transport port 616 to processing chamber 614 is opened, and another robot (not shown) places the substrate into the reactor on a pedestal of a first station shown in the reactor for processing. While the embodiment depicted in FIG. 6 includes load locks, it will be appreciated that, in some embodiments, direct entry of a substrate into a process station may be provided. In various embodiments, the soak gas is introduced to the station when the substrate is placed by the robot 606 on the pedestal 612.

The depicted processing chamber 614 comprises four process stations, numbered from 1 to 4 in the embodiment shown in FIG. 6. Each station has a heated pedestal (shown at 618 for station 1), and gas line inlets. It will be appreciated that in some embodiments, each process station may have different or multiple purposes. For example, in some embodiments, a process station may be switchable between an ALD and PEALD process mode. Additionally or alternatively, in some embodiments, processing chamber 614 may include one or more matched pairs of ALD and plasma-enhanced ALD process stations. While the depicted processing chamber 614 includes four stations, it will be understood that a processing chamber according to the present disclosure may have any suitable number of stations. For example, in some embodiments, a processing chamber may have five or more stations, while in other embodiments a processing chamber may have three or fewer stations.

FIG. 6 depicts an embodiment of a wafer handling system 690 for transferring substrates within processing chamber 614. In some embodiments, wafer handling system 690 may transfer substrates between various process stations and/or between a process station and a load lock. It will be appreciated that any suitable wafer handling system may be employed. Non-limiting examples include wafer carousels and wafer handling robots. FIG. 6 also depicts an embodiment of a system controller 650 employed to control process conditions and hardware states of process tool 600. System controller 650 may include one or more memory devices 656, one or more mass storage devices 654, and one or more processors 652. Processor 652 may include a CPU or computer, analog and/or digital input/output connections, stepper motor controller boards, etc. In some embodiments, system controller 650 includes machine-readable instructions for performing operations such as those described above with respect to FIGS. 2, 3, and 4.

In some embodiments, system controller 650 controls the activities of process tool 600. System controller 650 executes system control software 658 stored in mass storage device 654, loaded into memory device 656, and executed on processor 652. Alternatively, the control logic may be hard coded in the controller 650. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 658 may include instructions for controlling the timing, mixture of gases, amount of gas flow, chamber and/or station pressure, chamber and/or station temperature, substrate temperature, target power levels, RF power levels, substrate pedestal, chuck and/or susceptor position, and other parameters of a particular process performed by process tool 600. System control software 658 may be configured in any suitable way. For example, various process tool component subroutines or control objects may be written to control operation of the process tool components used to carry out various process tool processes. System control software 658 may be coded in any suitable computer readable programming language.

In some embodiments, system control software 658 may include input/output control (IOC) sequencing instructions for controlling the various parameters described above. Other computer software and/or programs stored on mass storage device 654 and/or memory device 656 associated with system controller 650 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 618 and to control the spacing between the substrate and other parts of process tool 600.

A process gas control program may include code for controlling gas composition (e.g., first precursor gas, soak gas, second reactant gas, and purge gases as described herein) and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. Alternatively, the heater control program may control delivery of a heat transfer gas (such as the soak gas) to the substrate.

A plasma control program may include code for setting RF power levels applied to the process electrodes in one or more process stations in accordance with the embodiments herein.

A pressure control program may include code for maintaining the pressure in the reaction chamber in accordance with the embodiments herein.

In some embodiments, there may be a user interface associated with system controller 650. The user interface may include a display screen, graphical software displays of the apparatus and/or process conditions, and user input devices such as pointing devices, keyboards, touch screens, microphones, etc.

In some embodiments, parameters adjusted by system controller 650 may relate to process conditions. Non-limiting examples include process gas composition and flow rates, temperature, pressure, plasma conditions (such as RF bias power levels), pressure, temperature, etc. These parameters may be provided to the user in the form of a recipe, which may be entered utilizing the user interface.

Signals for monitoring the process may be provided by analog and/or digital input connections of system controller 650 from various process tool sensors. The signals for controlling the process may be output on the analog and digital output connections of process tool 600. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 650 may provide program instructions for implementing the above-described deposition processes such as processes that employ a soak prior to initiating ALD for a substrate inserted into the reaction chamber, with the soak performed under any of the soak conditions described herein. The program instructions may control a variety of process parameters, such as direct current (DC) power level, RF bias power level, pressure, temperature, etc. The instructions may control the parameters to operate in-situ deposition of film stacks according to various embodiments described herein.

The system controller will typically include one or more memory devices and one or more processors configured to execute the instructions so that the apparatus will perform a method in accordance with disclosed embodiments. Machine-readable media containing instructions for controlling process operations in accordance with disclosed embodiments may be coupled to the system controller.

In some implementations, the system controller 650 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 650, depending on the processing conditions and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 650 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 650 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 650, in some implementations, may be a part of or coupled to a computer that is integrated with, coupled to the system, otherwise networked to the system, or a combination thereof. For example, the system controller 650 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 650 receives instructions in the form of data, which specify parameters for each of the processing steps to be performed during one or more operations. It should be understood that the parameters may be specific to the type of process to be performed and the type of tool that the system controller 650 is configured to interface with or control. Thus as described above, the system controller 650 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the system controller 650 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

An appropriate apparatus for performing the methods disclosed herein is further discussed and described in U.S. patent application Ser. No. 13/084,399, filed Apr. 11, 2011, and titled “PLASMA ACTIVATED CONFORMAL FILM DEPOSITION”; and Ser. No. 13/084,305, filed Apr. 11, 2011, and titled “SILICON NITRIDE FILMS AND METHODS,” each of which is incorporated herein in its entireties.

The apparatus/process described herein may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility. Lithographic patterning of a film typically includes some or all of the following operations, each operation enabled with a number of possible tools: (1) application of photoresist on a workpiece, i.e., substrate, using a spin-on or spray-on tool; (2) curing of photoresist using a hot plate or furnace or ultraviolet (UV) curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

### EXPERIMENTAL

### Experiment 1

An experiment was conducted for in-situ low temperature carbon deposition. One blanket carbon film was deposited using a temperature of about 85° C. and a pressure of about 0.5 Torr using methane gas diluted in argon gas and igniting a plasma at a power of 400 W for a 4-station chamber which resulted in a deposition rate of about 52 Å/minute. One blanket carbon film was deposited using a temperature of about 85° C. and a pressure of about 0.5 Torr using methane gas diluted in argon gas and igniting a plasma at a power of 800 W for a 4-station chamber which resulted in a deposition rate of about 96 Å/minute.

### Experiment 2

Silicon oxide was deposited on the blanket carbon films. Silicon oxide was deposited on a blanket carbon film using atomic layer deposition (ALD) with a silicon-containing precursor and an oxidant ignited in a plasma ignited at a power of 2 kW with a pulse duration of 0.6 seconds (having a plasma energy of 1200 J) for several cycles. The amount of carbon consumed when the silicon oxide was deposited was about 190 Å. Silicon oxide was deposited on a blanket carbon film using ALD with a silicon-containing precursor and an oxidant ignited in a plasma ignited at a power of 2 kW with a pulse duration of 1 second (having a plasma energy of 2000 J) for several cycles. The amount of carbon consumed when the silicon oxide was deposited was about 265 Å.

### Experiment 3

Silicon oxide was deposited with high plasma conditions onto a substrate with 46 nm height carbon-containing mandrels. Prior to deposition, the critical dimension of the top was about 17.3 nm, the critical dimension of the middle was about 17.2 nm, and the critical dimension of the bottom was about 18.8 nm. The core top to bottom delta was about 1.5. After deposition without using a sacrificial layer and without using soft ALD, the core height was about 43 nm, the top core critical dimension was about 13.9 nm, the middle core critical dimension was about 15.8, and the bottom core critical dimension was about 19.7 nm. The core top to bottom delta was about 5.8, which indicates damage to the core as a result of exposure to deposition conditions during deposition of silicon oxide.

In a first substrate, a sacrificial carbon layer is deposited on carbon-containing mandrels and a low temperature silicon oxide spacer is deposited over the sacrificial carbon layer. Carbon from the sacrificial carbon layer is consumed at different locations by the low temperature silicon oxide spacer deposition. In various embodiments, the low temperature silicon oxide deposition can consume between about 1 nm and about 5 nm of sacrificial carbon. A process that uses sacrificial carbon layer deposition and low temperature silicon oxide spacer deposition was evaluated for defects and low accumulation of defects was observed.

### Experiment 4

Six substrates of silicon oxide deposition were evaluated and compared. A first substrate involved atomic layer deposition (ALD) of silicon oxide using low plasma conditions without plasma treatment between ALD cycles. The density of the silicon oxide was about 2.0 g/cc and the modulus of the silicon oxide was about 45 GPa. A second substrate involved plasma treatment only after multiple cycles of ALD of silicon oxide, which resulted in a density of 2.02 g/cc and a modulus of 62 GPa. A third substrate involved plasma treatment every 20 cycles of soft ALD of silicon oxide and resulted in a density of 2.12 g/cc. A fourth substrate involved plasma treatment every 15 cycles of soft ALD of silicon oxide and resulted in a density of 2.15 g/cc. A fifth substrate involved plasma treatment every 13 cycles of soft ALD of silicon oxide and resulted in a density of 2.17 g/cc with a modulus of 66 GPa. A sixth substrate involved plasma treatment every 10 cycles of soft ALD of silicon oxide and resulted in a density of 2.20 g/cc and a modulus of 82 GPA.

These results suggest that plasma treatment substantially improves the modulus and density of the soft ALD film particularly around treating every 10-13 cycles of ALD.

### Experiment 5

Silicon oxide was deposited on four substrates using the same number of atomic layer deposition (ALD) cycles. On the first substrate, 240 cycles of ALD was performed using a silicon-containing precursor dose, purge, conversion with an oxidizing plasma at 2500 W for 1 second for a 4-station chamber, then purge. No plasma treatment was used.

On the second substrate, 240 cycles of ALD was performed using a silicon-containing precursor dose, purge, conversion with an oxidizing plasma at 500 W for a 4-station chamber, then purge, where after the first 10 cycles of ALD, plasma treatment was performed using high plasma power. After plasma treatment, subsequent cycles were performed using a silicon-containing precursor dose, purge, conversion with an oxidizing plasma at 2500 W for 1 second for a 4-station chamber, then purge.

On the third substrate, 240 cycles of ALD was performed using a silicon-containing precursor dose, purge, conversion with an oxidizing plasma at 500 W for a 4-station chamber, then purge, where after the first 20 cycles of ALD, plasma treatment was performed using high plasma power. After plasma treatment, subsequent cycles were performed using a silicon-containing precursor dose, purge, conversion with an oxidizing plasma at 2500 W for 1 second for a 4-station chamber, then purge.

On the fourth substrate, 240 cycles of ALD was performed using a silicon-containing precursor dose, purge, conversion with an oxidizing plasma at 500 W for a 4-station chamber, then purge, where after the first 30 cycles of ALD, plasma treatment was performed using high plasma power. After plasma treatment, subsequent cycles were performed using a silicon-containing precursor dose, purge, conversion with an oxidizing plasma at 2500 W for 1 second for a 4-station chamber, then purge.

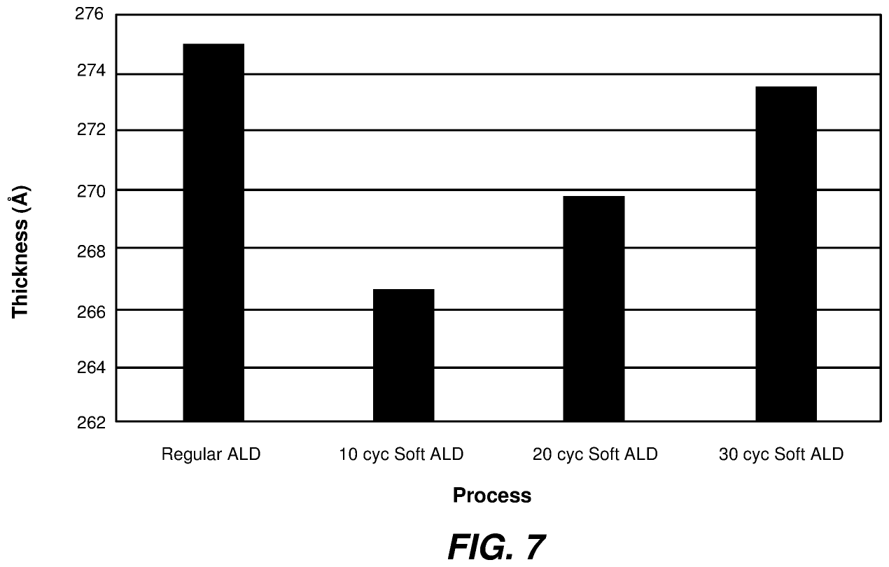

The results are shown in FIG. 7. As shown, results for regular ALD indicated significant native oxidation of the substrate because of the higher power, because 240 cycles of ALD is not expected to deposit 275 Å of film without oxidizing the substrate itself. For plasma treatment every 10 cycles, the film was densified to a thinner thickness with no damage. The experiments with plasma treatment every 20 and 30 cycles showed no damage, but the initial few layers were not fully densified, which is why increased thickness was observed. This suggests the plasma penetration for this particular plasma treatment process only penetrates to about 10 cycles of non-treated soft ALD material, so the 20 and 30 cycle processes resulted in layers of non-treated and treated soft ALD material, whereas the 10 cycle process resulted in an entire layer of treated soft ALD material. Leakage data also showed that the plasma treatment every 10 cycles avoided damage and had good densification.

Additional results for leakage and relative wet etch rate were evaluated and are summarized below in Tables 1-3.

TABLE 1
Leakage and Wet Etch Rate

| Experiment | Leakage @ 2 MV/cm |
|---|---|
| Soft ALD Process 10 cyc, 2500 W 10 s | 1.7436E−08 |
| Baseline, Regular ALD | 2.0545E−08 |
| 2500 W 1.0 s process | |

TABLE 2

| Experiment | WERR |
|---|---|
| Soft ALD Process 10 cyc, | 4.43 |
| 2500 W 10 s plasma treatment | |
| Soft ALD Process 20 cyc, | 4.61 |
| 2500 W 20 s plasma treatment | |
| Baseline, Regular ALD 2500 W, 1 s | 5.05 |

TABLE 3

| Plasma Conditions | Plasma | Leakage @ | Wet Etch Rate |
|---|---|---|---|
| during Conversion | Treatment? | 2 MV/cm | (Relative) |
| Cyclic ALD, 500 W, | 2500 W/10 s | 1.7436E−08 | 4.43 |
| treatment every 10 cyc | treatment | | |
| Cyclic ALD, 500 W, | 2500 W/20 s | | 4.61 |
| treatment every 20 cyc | treatment | | |
| Regular ALD, | No treatment | 2.0545E−08 | 5.05 |
| 2500 W/1 s | | | |

### Definitions and Precursors

### Definitions

The term “acyl,” or “alkanoyl,” as used interchangeably herein, represents groups of 1, 2, 3, 4, 5, 6, 7, 8 or more carbon atoms of a straight, branched, cyclic configuration, saturated, unsaturated and aromatic, and combinations thereof, or hydrogen, attached to the parent molecular group through a carbonyl group, as defined herein. This group is exemplified by formyl (—C(O)H), acetyl (Ac or —C(O)Me), propionyl, isobutyryl, butanoyl, and the like. In some embodiments, the acyl or alkanoyl group is —C(O)—R, in which R is hydrogen, an aliphatic group, or an aromatic group, as defined herein.

By “alkanoyloxy” is meant an alkanoyl group, as defined herein, attached to the parent molecular group through an oxy group, as defined herein. This group is exemplified by acetoxy (—OAc or —OC(O)Me). In some embodiments, the alkanoyloxy group is —OC(O)—R, in which R is hydrogen, an aliphatic group, or an aromatic group, as defined herein.

By “aliphatic” is meant a hydrocarbon group having at least one carbon atom to 50 carbon atoms (C₁₋₅₀), such as one to 25 carbon atoms (C₁₋₂₅), or one to ten carbon atoms (C₁₋₁₀), and which includes alkanes (or alkyl), alkenes (or alkenyl), alkynes (or alkynyl), including cyclic versions thereof, and further including straight- and branched-chain arrangements, and all stereo and position isomers as well. An aliphatic group is unsubstituted or substituted, e.g., by a functional group described herein. For example, the aliphatic group can be substituted with one or more substitution groups, as described herein for alkyl.

By “aliphatic-carbonyl” is meant an aliphatic group that is or can be coupled to a compound disclosed herein, wherein the aliphatic group is or becomes coupled through a carbonyl group (—C(O)—). In some embodiments, the aliphatic-carbonyl group is —C(O)—R, in which R is an optionally substituted aliphatic group, as defined herein.

By “aliphatic-carbonyloxy” is meant an aliphatic group that is or can be coupled to a compound disclosed herein, wherein the aliphatic group is or becomes coupled through a carbonyloxy group (—OC(O)—). In some embodiments, the aliphatic-carbonyloxy group is —OC(O)—R, in which R is an optionally substituted aliphatic group, as defined herein.

By “aliphatic-oxy” is meant an aliphatic group that is or can be coupled to a compound disclosed herein, wherein the aliphatic group is or becomes coupled through an oxy group (—C(O)—). In some embodiments, the aliphatic-oxy group is —O—R, in which R is an optionally substituted aliphatic group, as defined herein.

By “aliphatic-oxycarbonyl” is meant an aliphatic group that is or can be coupled to a compound disclosed herein, wherein the aliphatic group is or becomes coupled through an oxycarbonyl group (—C(O)O—). In some embodiments, the aliphatic-oxycarbonyl group is —C(O)O—R, in which R is an optionally substituted aliphatic group, as defined herein.

By “alkyl-aryl,” “alkenyl-aryl,” and “alkynyl-aryl” is meant an alkyl, alkenyl, or alkynyl group, respectively and as defined herein, that is or can be coupled (or attached) to the parent molecular group through an aryl group, as defined herein. The alkyl-aryl, alkenyl-aryl, and/or alkynyl-aryl group can be substituted or unsubstituted. For example, the alkyl-aryl, alkenyl-aryl, and/or alkynyl-aryl group can be substituted with one or more substitution groups, as described herein for alkyl and/or aryl. Exemplary unsubstituted alkyl-aryl groups are of from 7 to 16 carbons (C₇₋₁₆ alkyl-aryl), as well as those having an alkyl group with 1 to 6 carbons and an aryl group with 4 to 18 carbons (i.e., C₁₋₆ alkyl-C₄₋₁₈ aryl). Exemplary unsubstituted alkenyl-aryl groups are of from 7 to 16 carbons (C₇₋₁₆ alkenyl-aryl), as well as those having an alkenyl group with 2 to 6 carbons and an aryl group with 4 to 18 carbons (i.e., C₂₋₆ alkenyl-C₄₋₁₈ aryl). Exemplary unsubstituted alkynyl-aryl groups are of from 7 to 16 carbons (C₇₋₁₆ alkynyl-aryl), as well as those having an alkynyl group with 2 to 6 carbons and an aryl group with 4 to 18 carbons (i.e., C₂₋₆ alkynyl-C₄₋₁₈ aryl). In some embodiments, the alkyl-aryl group is -L-R, in which L is an aryl group or an arylene group, as defined herein, and R is an alkyl group, as defined herein. In some embodiments, the alkenyl-aryl group is -L-R, in which L is an aryl group or an arylene group, as defined herein, and R is an alkenyl group, as defined herein. In some embodiments, the alkynyl-aryl group is -L-R, in which L is an aryl group or an arylene group, as defined herein, and R is an alkynyl group, as defined herein.

By “alkenyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon double bond, wherein the unsaturated monovalent hydrocarbon can be derived from removing one hydrogen atom from one carbon atom of a parent alkene. An alkenyl group can be branched, straight-chain, cyclic (e.g., cycloalkenyl), cis, or trans (e.g., E or Z). An exemplary alkenyl includes an optionally substituted C₂₋₂₄ alkyl group having one or more double bonds. The alkenyl group can be monovalent or multivalent (e.g., bivalent) by removing one or more hydrogens to form appropriate attachment to the parent molecular group or appropriate attachment between the parent molecular group and another substitution. The alkenyl group can also be substituted or unsubstituted. For example, the alkenyl group can be substituted with one or more substitution groups, as described herein for alkyl. Non-limiting alkenyl groups include allyl (All), vinyl (Vi), 1-butenyl, 2-butenyl, and the like.

By “alkoxy” is meant —OR, where R is an optionally substituted aliphatic group, as described herein. Exemplary alkoxy groups include, but are not limited to, methoxy, ethoxy, n-propoxy, isopropoxy, n-butoxy, t-butoxy, sec-butoxy, n-pentoxy, trihaloalkoxy, such as trifluoromethoxy, etc. The alkoxy group can be substituted or unsubstituted. For example, the alkoxy group can be substituted with one or more substitution groups, as described herein for alkyl. Exemplary unsubstituted alkoxy groups include C₁₋₃, C₁₋₆, C₁₋₁₂, C₁₋₁₆, C₁₋₁₈, C₁₋₂₀, or C₁₋₂₄ alkoxy groups.

By “alkoxyalkyl” is meant an alkyl group, as defined herein, which is substituted with an alkoxy group, as defined herein. Exemplary unsubstituted alkoxyalkyl groups include between 2 to 12 carbons (C₂₋₁₂ alkoxyalkyl), as well as those having an alkyl group with 1 to 6 carbons and an alkoxy group with 1 to 6 carbons (i.e., C₁₋₆ alkoxy-C₁₋₆ alkyl). In some embodiments, the alkoxyalkyl group is -L-O—R, in which each of L and R is, independently, an alkyl group, as defined herein.

By “alkoxycarbonyl” is meant —C(O)—OR, where R is an optionally substituted aliphatic group, as described herein. In particular embodiments, the alkoxycarbonyl group is —C(O)—OAk, in which Ak is an alkyl group, as defined herein. The alkoxycarbonyl group can be substituted or unsubstituted. For example, the alkoxycarbonyl group can be substituted with one or more substitution groups, as described herein for alkyl. Exemplary unsubstituted alkoxycarbonyl groups include C₂₋₃, C₂₋₆, C₂₋₇, C₂₋₁₂, C₂₋₁₆, C₂₋₁₈, C₂₋₂₀, or C₂₋₂₄ alkoxycarbonyl groups.

By “alkyl” is meant a saturated monovalent hydrocarbon having at least one carbon atom to 50 carbon atoms (C₁₋₅₀), such as one to 25 carbon atoms (C₁₋₂₅), or one to ten carbon atoms (C₁₋₁₀), wherein the saturated monovalent hydrocarbon can be derived from removing one hydrogen atom from one carbon atom of a parent compound (e.g., alkane). An alkyl group can be branched, straight-chain, or cyclic (e.g., cycloalkyl). An exemplary alkyl includes a branched or unbranched saturated hydrocarbon group of 1 to 24 carbon atoms, such as methyl (Me), ethyl (Et), n-propyl (nPr), iso-propyl (iPr), n-butyl (nBu), iso-butyl (iBu), sec-butyl (sBu), tert-butyl (tBu), pentyl (Pe), n-pentyl (nPe), isopentyl (iPe), s-pentyl (sPe), neopentyl (neoPe), tert-pentyl (tPe), hexyl (Hx), heptyl (Hp), octyl (Oc), nonyl (Nn), decyl (De), dodecyl, tetradecyl, hexadecyl, eicosyl, tetracosyl, and the like. The alkyl group can also be substituted or unsubstituted. The alkyl group can be monovalent or multivalent (e.g., bivalent) by removing one or more hydrogens to form appropriate attachment to the parent molecular group or appropriate attachment between the parent molecular group and another substitution. For example, the alkyl group can be substituted with one, two, three or, in the case of alkyl groups of two carbons or more, four substituents independently selected from the group consisting of: (1) C₁₋₆ alkoxy (e.g., —O—R, in which R is C₁₋₆ alkyl); (2) C₁₋₆ alkylsulfinyl (e.g., —S(O)—R, in which R is C₁₋₆ alkyl); (3) C₁₋₆ alkylsulfonyl (e.g., —SO₂—R, in which R is C₁₋₆ alkyl); (4) amino (e.g., —NR¹R², where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, can form a heterocyclyl group, as defined herein); (5) aryl; (6) arylalkoxy (e.g., —O-L-R, in which L is alkyl and R is aryl); (7) aryloyl (e.g., —C(O)—R, in which R is aryl); (8) azido (e.g., —N₃); (9) cyano (e.g., —CN); (10) aldehyde (e.g., —C(O)H); (11) C₃₋₈ cycloalkyl; (12) halo; (13) heterocyclyl (e.g., as defined herein, such as a 5-, 6- or 7-membered ring containing one, two, three, or four non-carbon heteroatoms); (14) heterocyclyloxy (e.g., —O—R, in which R is heterocyclyl, as defined herein); (15) heterocyclyloyl (e.g., —C(O)—R, in which R is heterocyclyl, as defined herein); (16) hydroxyl (e.g., —OH); (17) N-protected amino; (18) nitro (e.g., —NO₂); (19) oxo (e.g., =O); (20) C₁₋₆ thioalkyl (e.g., —S—R, in which R is alkyl); (21) thiol (e.g., —SH); (22) —CO₂R¹, where R¹ is selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (23) —C(O)NR¹R², where each of R¹ and R² is, independently, selected from the group consisting of (a) hydrogen, (b) C₁₋₆ alkyl, (c) C₄₋₁₈aryl, and (d) C₄₋₁₈aryl-C₁₋₆ alkyl (e.g., -L-R, in which L is C₁₋₆ alkyl and R is C₄₋₁₈aryl); (24) —SO₂R¹, where R¹ is selected from the group consisting of (a) C₁₋₆ alkyl, (b) C₄₋₁₈ aryl, and (c) C₄₋₁₈aryl-C₁₋₆ alkyl (e.g., -L-R, in which L is C₁₋₆ alkyl and R is C₄₋₁₈aryl); (25) —SO₂NR¹R², where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); and (26) —NR¹R², where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₄₋₁₈ aryl-C₁₋₆ alkyl (e.g., -L-R, in which L is C₁₋₆ alkyl and R is C₄₋₁₈ aryl), (h) C₃₋₈ cycloalkyl, and (i) C₃₋₈ cycloalkyl-C₁₋₆ alkyl (e.g., -L-R, in which L is C₁₋₆ alkyl and R is C₃₋₈ cycloalkyl), wherein in one embodiment no two groups are bound to the nitrogen atom through a carbonyl group or a sulfonyl group. The alkyl group can be a primary, secondary, or tertiary alkyl group substituted with one or more substituents (e.g., one or more halo or alkoxy). In some embodiments, the unsubstituted alkyl group is a C₁₋₃, C₁₋₆, C₁₋₁₂, C₁₋₁₆, C₁₋₁₈, C₁₋₂₀, or C₁₋₂₄ alkyl group.

By “alkylene,” “alkenylene,” or “alkynylene” is meant a multivalent (e.g., bivalent) form of an alkyl, alkenyl, or alkynyl group, respectively, as described herein. Exemplary alkylene groups include methylene, ethylene, propylene, butylene, etc. In some embodiments, the alkylene group is a C₁₋₃, C₁₋₆, C₁₋₁₂, C₁₋₁₆, C₁₋₁₈, C₁₋₂₀, C₁₋₂₄, C₂₋₃, C₂₋₆, C₂₋₁₂, C₂₋₁₆, C₂₋₁₈, C₂₋₂₀, or C₂₋₂₄ alkylene group. In other embodiments, the alkylene group is a C₂₋₃, C₂₋₆, C₂₋₁₂, C₂₋₁₆, C₂₋₁₈, C₂₋₂₀, or C₂₋₂₄ alkenylene or alkynylene group. The alkylene, alkenylene, or alkynylene group can be branched or unbranched. The alkylene, alkenylene, or alkynylene group can also be substituted or unsubstituted. For example, the alkylene, alkenylene, or alkynylene group can be substituted with one or more substitution groups, as described herein for alkyl.

By “alkylsulfinyl” is meant an alkyl group, as defined herein, attached to the parent molecular group through an —S(O)— group. In some embodiments, the unsubstituted alkylsulfinyl group is a C₁₋₆ or C₁₋₁₂ alkylsulfinyl group. In other embodiments, the alkylsulfinyl group is —S(O)—R, in which R is an alkyl group, as defined herein.

By “alkylsulfinylalkyl” is meant an alkyl group, as defined herein, substituted by an alkylsulfinyl group. In some embodiments, the unsubstituted alkylsulfinylalkyl group is a C₂₋₁₂ or C₂₋₂₄ alkylsulfinylalkyl group (e.g., C₁₋₆ alkylsulfinyl-C₁₋₆ alkyl or C₁₋₁₂ alkylsulfinyl-C₁₋₁₂ alkyl). In other embodiments, the alkylsulfinylalkyl group is -L-S(O)—R, in which each of L and R is, independently, an alkyl group, as defined herein.

By “alkylsulfonyl” is meant an alkyl group, as defined herein, attached to the parent molecular group through an —SO₂— group. In some embodiments, the unsubstituted alkylsulfonyl group is a C₁₋₆ or C₁₋₁₂ alkylsulfonyl group. In other embodiments, the alkylsulfonyl group is —SO₂ —R, where R is an optionally substituted alkyl (e.g., as described herein, including optionally substituted C₁₋₁₂ alkyl, haloalkyl, or perfluoroalkyl).

By “alkylsulfonylalkyl” is meant an alkyl group, as defined herein, substituted by an alkylsulfonyl group. In some embodiments, the unsubstituted alkylsulfonylalkyl group is a C₂₋₁₂ or C₂₋₂₄ alkylsulfonylalkyl group (e.g., C₁₋₆ alkylsulfonyl-C₁₋₆ alkyl or C₁₋₁₂ alkylsulfonyl-C₁₋₁₂ alkyl). In other embodiments, the alkylsulfonylalkyl group is -L-SO₂—R, in which each of L and R is, independently, an alkyl group, as defined herein.

By “alkynyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon triple bond, wherein the unsaturated monovalent hydrocarbon can be derived from removing one hydrogen atom from one carbon atom of a parent alkyne. An alkynyl group can be branched, straight-chain, or cyclic (e.g., cycloalkynyl). An exemplary alkynyl includes an optionally substituted C₂₋₂₄ alkyl group having one or more triple bonds. The alkynyl group can be cyclic or acyclic and is exemplified by ethynyl, 1-propynyl, and the like. The alkynyl group can be monovalent or multivalent (e.g., bivalent) by removing one or more hydrogens to form appropriate attachment to the parent molecular group or appropriate attachment between the parent molecular group and another substitution. The alkynyl group can also be substituted or unsubstituted. For example, the alkynyl group can be substituted with one or more substitution groups, as described herein for alkyl.

By “ambient temperature” is meant a temperature ranging from 16° C. to 26° C., such as from 19° C. to 25° C. or from 20° C. to 25° C.

By “amide” is mean —C(O)NR¹R² or —NHCOR¹, where each of R¹ and R² is, independently, selected from hydrogen, aliphatic, heteroaliphatic, aromatic, as defined herein, or any combination thereof, or where R¹ and R², taken together with the nitrogen atom to which each are attached, can form a heterocyclyl group, as defined herein.

By “amino” is meant —NR¹R², where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where R¹ and R², taken together with the nitrogen atom to which each are attached, can form a heterocyclyl group, as defined herein. In particular embodiments, each of R¹ and R² is, independently, H, optionally substituted alkyl, optionally substituted alkoxy, optionally substituted aryl, optionally substituted aryloxy, optionally substituted alkyl-aryl, optionally substituted aryl-alkyl, optionally substituted silyl, or optionally substituted silyloxy. In particular embodiments, R¹ and R² can be taken together, with the nitrogen atom to which each is attached, to form an optionally substituted heterocyclyl.

By “aminoalkyl” is meant an alkyl group, as defined herein, substituted by an amino group, as defined herein. In some embodiments, the aminoalkyl group is -L-NR¹R², in which L is an alkyl group, as defined herein, and each of R¹ and R² is, independently, selected from hydrogen, aliphatic, heteroaliphatic, or aromatic, as defined herein, or any combination thereof; or R¹ and R², taken together with the nitrogen atom to which each are attached, can form a heterocyclyl group, as defined herein. In other embodiments, the aminoalkyl group is -L-C(NR¹R²)(R³)—R⁴, in which L is a covalent bond or an alkyl group, as defined herein; each of R¹ and R² is, independently, selected from hydrogen, aliphatic, heteroaliphatic, or aromatic, as defined herein, or any combination thereof; or R¹ and R², taken together with the nitrogen atom to which each are attached, can form a heterocyclyl group, as defined herein; and each of R³ and R⁴ is, independently, H or alkyl, as defined herein.

By “aminooxy” is meant an oxy group, as defined herein, substituted by an amino group, as defined herein. In some embodiments, the aminooxy group is —O—NR¹R², in which each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or R¹ and R², taken together with the nitrogen atom to which each are attached, can form a heterocyclyl group, as defined herein. In particular embodiments, each of R¹ and R² is, independently, H, optionally substituted alkyl, optionally substituted alkoxy, optionally substituted aryl, optionally substituted aryloxy, optionally substituted alkyl-aryl, optionally substituted aryl-alkyl, optionally substituted silyl, or optionally substituted silyloxy.

By “aromatic” is meant a cyclic, conjugated group or moiety of, unless specified otherwise, from 5 to 15 ring atoms having a single ring (e.g., phenyl) or multiple condensed rings in which at least one ring is aromatic (e.g., naphthyl, indolyl, or pyrazolopyridinyl); that is, at least one ring, and optionally multiple condensed rings, have a continuous, delocalized π-electron system. Typically, the number of out of plane π-electrons corresponds to the Huckel rule (4n+2). The point of attachment to the parent structure typically is through an aromatic portion of the condensed ring system. An aromatic group is unsubstituted or substituted, e.g., by a functional group described herein. For example, the aromatic group can be substituted with one or more substitution groups, as described herein for alkyl and/or aryl.

By “aromatic-carbonyl” is meant an aromatic group that is or can be coupled to a compound disclosed herein, wherein the aromatic group is or becomes coupled through a carbonyl group (—C(O)—). In some embodiments, the aromatic-carbonyl group is —C(O)—R, in which R is an optionally substituted aromatic group, as defined herein.

By “aromatic-carbonyloxy” is meant an aromatic group that is or can be coupled to a compound disclosed herein, wherein the aromatic group is or becomes coupled through a carbonyloxy group (—OC(O)—). In some embodiments, the aromatic-carbonyloxy group is —OC(O)—R, in which R is an optionally substituted aromatic group, as defined herein.

By “aromatic-oxy” is meant an aromatic group that is or can be coupled to a compound disclosed herein, wherein the aromatic group is or becomes coupled through an oxy group (—O—). In some embodiments, the aromatic-oxy group is —O—R, in which R is an optionally substituted aromatic group, as defined herein.

By “aromatic-oxycarbonyl” is meant an aromatic group that is or can be coupled to a compound disclosed herein, wherein the aromatic group is or becomes coupled through an oxycarbonyl group (—C(O)O—). In some embodiments, the aromatic-carbonyl group is —C(O)O—R, in which R is an optionally substituted aromatic group, as defined herein.

By “aryl” is meant an aromatic carbocyclic group comprising at least five carbon atoms to 15 carbon atoms (C₅₋₁₅), such as five to ten carbon atoms (C₅₋₁₀), having a single ring or multiple condensed rings, which condensed rings can or may not be aromatic provided that the point of attachment to a remaining position of the compounds disclosed herein is through an atom of the aromatic carbocyclic group. Aryl groups may be substituted with one or more groups other than hydrogen, such as aliphatic, heteroaliphatic, aromatic, other functional groups, or any combination thereof. Exemplary aryl groups include, but are not limited to, benzyl, naphthalene, phenyl, biphenyl, phenoxybenzene, and the like. The term aryl also includes heteroaryl, which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term non-heteroaryl, which is also included in the term aryl, defines a group that contains an aromatic group that does not contain a heteroatom. The aryl group can be substituted or unsubstituted. The aryl group can be substituted with one, two, three, four, or five substituents independently selected from the group consisting of: (1) C₁₋₆ alkanoyl (e.g., —C(O)—R, in which R is C₁₋₆ alkyl); (2) C₁₋₆ alkyl; (3) C₁₋₆ alkoxy (e.g., —O—R, in which R is C₁₋₆ alkyl); (4) C₁₋₆ alkoxy-C₁₋₆ alkyl (e.g., -L-O—R, in which each of L and R is, independently, C₁₋₆ alkyl); (5) C₁₋₆ alkylsulfinyl (e.g., —S(O)—R, in which R is C₁₋₆ alkyl); (6) C₁₋₆ alkylsulfinyl-C₁₋₆ alkyl (e.g., -L-S(O)—R, in which each of L and R is, independently, C₁₋₆ alkyl); (7) C₁₋₆ alkylsulfonyl (e.g., —SO₂—R, in which R is C₁₋₆ alkyl); (8) C₁₋₆ alkylsulfonyl-C₁₋₆ alkyl (e.g., -L-SO₂—R, in which each of L and R is, independently, C₁₋₆ alkyl); (9) aryl; (10) amino (e.g., —NR¹R², where each of R¹ and R² is, independently, selected from hydrogen, aliphatic, heteroaliphatic, haloaliphatic, haloheteroaliphatic, aromatic, as defined herein, or any combination thereof; or R¹ and R², taken together with the nitrogen atom to which each are attached, can form a heterocyclyl group, as defined herein); (11) C₁₋₆ aminoalkyl (e.g., -L¹-NR¹R² or -L²-C(NR¹R²)(R³)—R⁴, in which L¹ is C₁₋₆ alkyl; L² is a covalent bond or C₁₋₆ alkyl; each of R¹ and R² is, independently, selected from hydrogen, aliphatic, heteroaliphatic, haloaliphatic, haloheteroaliphatic, aromatic, as defined herein, or any combination thereof; or R¹ and R², taken together with the nitrogen atom to which each are attached, can form a heterocyclyl group, as defined herein; and each of R³ and R⁴ is, independently, H or C₁₋₆ alkyl); (12) heteroaryl; (13) C₄₋₁₈ aryl-C₁₋₆ alkyl (e.g., -L-R, in which L is C₁₋₆ alkyl and R is C₄₋₁₈ aryl); (14) aryloyl (e.g., —C(O)—R, in which R is aryl); (15) azido (e.g., —N₃); (16) cyano (e.g., —CN); (17) C₁₋₆ azidoalkyl (e.g., -L-N₃, in which L is C₁₋₆ alkyl); (18) aldehyde (e.g., —C(O)H); (19) aldehyde-C₁₋₆ alkyl (e.g., -L-C(O)H, in which L is C₁₋₆ alkyl); (20) C₃₋₈ cycloalkyl; (21) C₃₋₈ cycloalkyl-C₁₋₆ alkyl (e.g., -L-R, in which L is C₁₋₆ alkyl and R is C₃₋₈ cycloalkyl); (22) halo; (23) C₁₋₆ haloalkyl (e.g., -L¹-X or -L²-C(X)(R¹)—R², in which L¹ is C₁₋₆ alkyl; L² is a covalent bond or C₁₋₆ alkyl; X is fluoro, bromo, chloro, or iodo; and each of R¹ and R² is, independently, H or C₁₋₆ alkyl); (24) heterocyclyl (e.g., as defined herein, such as a 5-, 6- or 7-membered ring containing one, two, three, or four non-carbon heteroatoms); (25) heterocyclyloxy (e.g., —O—R, in which R is heterocyclyl, as defined herein); (26) heterocyclyloyl (e.g., —C(O)—R, in which R is heterocyclyl, as defined herein); (27) hydroxyl (—OH); (28) C₁₋₆ hydroxyalkyl (e.g., -L¹-OH or -L²-C(OH)(R¹)—R², in which L¹ is C₁₋₆ alkyl; L² is a covalent bond or alkyl; and each of R¹ and R² is, independently, H or C₁₋₆ alkyl, as defined herein); (29) nitro; (30) C₁₋₆ nitroalkyl (e.g., -L¹-NO or -L²-C(NO)(R¹)—R², in which L¹ is C₁₋₆ alkyl; L² is a covalent bond or alkyl; and each of R¹ and R² is, independently, H or C₁₋₆ alkyl, as defined herein); (31) N-protected amino; (32) N-protected amino-C₁₋₆ alkyl; (33) oxo (e.g., =O); (34) C₁₋₆ thioalkyl (e.g., —S—R, in which R is C₁₋₆ alkyl); (35) thio-C₁₋₆ alkoxy-C₁₋₆ alkyl (e.g., -L-S—R, in which each of L and R is, independently, C₁₋₆ alkyl); (36) —(CH₂)ᵣCO₂R¹, where r is an integer of from zero to four, and R¹ is selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (37) —(CH₂)ᵣCONR¹R², where r is an integer of from zero to four and where each R¹ and R² is independently selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (38) —(CH₂)ᵣSO₂R¹, where r is an integer of from zero to four and where R¹ is selected from the group consisting of (a) C₁₋₆ alkyl, (b) C₄₋₁₈ aryl, and (c) C₄₋₁₈ aryl-C₁₋₆ alkyl (e.g., -L-R, in which L is C₁₋₆ alkyl and R is C₄₋₁₈ aryl); (39) —(CH₂)ᵣSO₂NR′R², where r is an integer of from zero to four and where each of R¹ and R² is, independently, selected from the group consisting of (a) hydrogen, (b) C₁₋₆ alkyl, (c) C₄₋₁₈aryl, and (d) C₄₋₁₈aryl-C₁₋₆ alkyl (e.g., -L-R, in which L is C₁₋₆ alkyl and R is C₄₋₁₈ aryl); (40) —(CH₂)ᵣNR¹R², where r is an integer of from zero to four and where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₄₋₁₈ aryl-C₁₋₆ alkyl (e.g., -L-R, in which L is C₁₋₆ alkyl and R is C₄₋₁₈aryl), (h) C₃₋₈ cycloalkyl, and (i) C₃₋₈ cycloalkyl-C₁₋₆ alkyl (e.g., -L-R, in which L is C₁₋₆ alkyl and R is C₃₋₈ cycloalkyl), wherein in one embodiment no two groups are bound to the nitrogen atom through a carbonyl group or a sulfonyl group; (41) thiol (e.g., —SH); (42) perfluoroalkyl (e.g., —(CF₂)ₙCF₃, in which n is an integer from 0 to 10); (43) perfluoroalkoxy (e.g., —O—(CF₂)ₙCF₃, in which n is an integer from 0 to 10); (44) aryloxy (e.g., —O—R, in which R is aryl); (45) cycloalkoxy (e.g., —O—R, in which R is cycloalkyl); (46) cycloalkylalkoxy (e.g., —O-L-R, in which L is alkyl and R is cycloalkyl); and (47) arylalkoxy (e.g., —O-L-R, in which L is alkyl and R is aryl). In particular embodiments, an unsubstituted aryl group is a C₄₋₁₈, C₄₋₁₄, C₄₋₁₂, C₄₋₁₀, C₆₋₁₈, C₆₋₁₄, C₆₋₁₂, or C₆₋₁₀ aryl group.

By “aryl-alkyl,” “aryl-alkenyl,” and “aryl-alkynyl” is meant an aryl group, as defined herein, that is or can be coupled (or attached) to the parent molecular group through an alkyl, alkenyl, or alkynyl group, respectively, as defined herein. The aryl-alkyl, aryl-alkenyl, and/or aryl-alkynyl group can be substituted or unsubstituted. For example, the aryl-alkyl, aryl-alkenyl, and/or aryl-alkynyl group can be substituted with one or more substitution groups, as described herein for aryl and/or alkyl. Exemplary unsubstituted aryl-alkyl groups are of from 7 to 16 carbons (C₇₋₁₆ aryl-alkyl), as well as those having an aryl group with 4 to 18 carbons and an alkyl group with 1 to 6 carbons (i.e., C₄₋₁₈aryl-C₁₋₆ alkyl). Exemplary unsubstituted aryl-alkenyl groups are of from 7 to 16 carbons (C₇₋₁₆ aryl-alkenyl), as well as those having an aryl group with 4 to 18 carbons and an alkenyl group with 2 to 6 carbons (i.e., C₄₋₁₈ aryl-C₂₋₆ alkenyl). Exemplary unsubstituted aryl-alkynyl groups are of from 7 to 16 carbons (C₇₋₁₆ aryl-alkynyl), as well as those having an aryl group with 4 to 18 carbons and an alkynyl group with 2 to 6 carbons (i.e., C₄₋₁₈aryl-C₂₋₆ alkynyl). In some embodiments, the aryl-alkyl group is -L-R, in which L is an alkyl group or an alkylene group, as defined herein, and R is an aryl group, as defined herein. In some embodiments, the aryl-alkenyl group is -L-R, in which L is an alkenyl group or an alkenylene group, as defined herein, and R is an aryl group, as defined herein. In some embodiments, the aryl-alkynyl group is -L-R, in which L is an alkynyl group or an alkynylene group, as defined herein, and R is an aryl group, as defined herein.

By “arylene” is meant a multivalent (e.g., bivalent) form of an aryl group, as described herein. Exemplary arylene groups include phenylene, naphthylene, biphenylene, triphenylene, diphenyl ether, acenaphthenylene, anthrylene, or phenanthrylene. In some embodiments, the arylene group is a C₄₋₁₈, C₄₋₁₄, C₄₋₁₂, C₄₋₁₀, C₆₋₁₈, C₆₋₁₄, C₆₋₁₂, or C₆₋₁₀ arylene group. The arylene group can be branched or unbranched. The arylene group can also be substituted or unsubstituted. For example, the arylene group can be substituted with one or more substitution groups, as described herein for aryl.

By “arylalkoxy” is meant an aryl-alkyl group, as defined herein, attached to the parent molecular group through an oxygen atom. In some embodiments, the arylalkoxy group is —O-L-R, in which L is an alkyl group, as defined herein, and R is an aryl group, as defined herein.

By “aryloxy” is meant —OR, where R is an optionally substituted aryl group, as described herein. In some embodiments, an unsubstituted aryloxy group is a C₄₋₁₈ or C₆₋₁₈aryloxy group. In other embodiments, R is an aryl group that is optionally substituted with alkyl, alkanoyl, amino, hydroxyl, and the like.

By “aryloxycarbonyl” is meant an aryloxy group, as defined herein, that is attached to the parent molecular group through a carbonyl group. In some embodiments, an unsubstituted aryloxycarbonyl group is a C₅₋₁₉ aryloxycarbonyl group. In other embodiments, the aryloxycarbonyl group is —C(O)O—R, in which R is an aryl group, as defined herein.

By “aryloyl” is meant an aryl group that is attached to the parent molecular group through a carbonyl group. In some embodiments, an unsubstituted aryloyl group is a C₇₋₁₁ aryloyl or C₅₋₁₉ aryloyl group. In other embodiments, the aryloyl group is —C(O)—R, in which R is an aryl group, as defined herein.

By “aryloyloxy” is meant an aryloyl group, as defined herein, that is attached to the parent molecular group through an oxy group. In some embodiments, an unsubstituted aryloyloxy group is a C₅₋₁₉ aryloyloxy group. In other embodiments, the aryloyloxy group is —OC(O)—R, in which R is an aryl group, as defined herein.

By “azido” is meant an —N₃ group.

By “azidoalkyl” is meant an azido group attached to the parent molecular group through an alkyl group, as defined herein. In some embodiments, the azidoalkyl group is -L-N₃, in which L is an alkyl group, as defined herein.

By “azo” is meant an —N═N— group.

By “carbamoyl” is meant an amino group attached to the parent molecular group through a carbonyl group, as defined herein. In some embodiments, the carbamoyl is —C(O)NR¹R² group, where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where R¹ and R², taken together with the nitrogen atom to which each are attached, can form a heterocyclyl group, as defined herein.

By “carbamoyloxy” is meant a carbamoyl group, as defined herein, attached to the parent molecular group through n oxy group, as defined herein. In some embodiments, the carbamoyl is —OC(O)NR¹R² group, where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where R¹ and R², taken together with the nitrogen atom to which each are attached, can form a heterocyclyl group, as defined herein.

By “carbonimidoyl” is meant a —C(NR)— group. In some embodiments, R is selected from hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, optionally substituted silyloxy, as defined herein, or any combination thereof.

By “carbonyl” is meant a —C(O)— group, which can also be represented as >C═O.

By “carboxyl” is meant a —CO₂H group or an anion thereof.

By “catalyst” is meant a compound, usually present in small amounts relative to reactants, capable of catalyzing a synthetic reaction, as would be readily understood by a person of ordinary skill in the art. In some embodiments, catalysts may include transition metal coordination complex.

By “cyanato” is meant a —OCN group.

By “cyano” is meant a —CN group.

By “cycloaliphatic” is meant an aliphatic group, as defined herein, that is cyclic.

By “cycloalkoxy” is meant a cycloalkyl group, as defined herein, attached to the parent molecular group through an oxygen atom. In some embodiments, the cycloalkoxy group is —O—R, in which R is a cycloalkyl group, as defined herein.

By “cycloalkylalkoxy” is meant a —O-L-R group, in which L is an alkyl group or an alkylene group, as defined herein, and R is a cycloalkyl group, as defined herein.

By “cycloalkyl” is meant a monovalent saturated or unsaturated non-aromatic cyclic hydrocarbon group of from three to eight carbons, unless otherwise specified, and is exemplified by cyclopropyl, cyclobutyl, cyclopentyl, cyclohexyl, cycloheptyl, bicyclo[2.2.1.heptyl], and the like. The cycloalkyl group can also be substituted or unsubstituted. For example, the cycloalkyl group can be substituted with one or more groups including those described herein for alkyl. Further, cycloalkyl may include one or more double bonds and/or triple bonds.

By “cycloheteroaliphatic” is meant a heteroaliphatic group, as defined herein, that is cyclic.

By “disilanyl” is meant a group containing an Si—Si bond. In some embodiments, the disilanyl group is a —SiR^{S1}R^{S2}—SiR^{S3}R^{S4}R^{S5} or —SiR^{S1}R^{S2}—SiR^{S3}R^{S4}— group, in which each of R^{S1}, R^{S2}, R^{S3}, R^{S4}, and R^{S5} is, independently, H, optionally substituted aliphatic, optionally substituted heteroaliphatic, optionally substituted aromatic, optionally substituted heteroaromatic, or optionally substituted amino.

By “disulfide” is meant —SSR, where R is selected from hydrogen, aliphatic, heteroaliphatic, haloaliphatic, haloheteroaliphatic, aromatic, as defined herein, or any combination thereof.

By “electron-donating group” is meant a functional group capable of donating at least a portion of its electron density into the ring to which it is directly attached, such as by resonance.

By “electron-withdrawing group” is meant a functional group capable of accepting electron density from the ring to which it is directly attached, such as by inductive electron withdrawal.

By “halo” is meant F, Cl, Br, or I.

By “haloaliphatic” is meant an aliphatic group, as defined herein, in which one or more hydrogen atoms, such as one to 10 hydrogen atoms, independently is replaced with a halogen atom, such as fluoro, bromo, chloro, or iodo.

By “haloalkyl” is meant an alkyl group, as defined herein, where one or more hydrogen atoms, such as one to 10 hydrogen atoms, independently is replaced with a halogen atom, such as fluoro, bromo, chloro, or iodo. In an independent embodiment, haloalkyl can be a —CX₃ group, wherein each X independently can be selected from fluoro, bromo, chloro, or iodo. In some embodiments, the haloalkyl group is -L-X, in which L is an alkyl group, as defined herein, and X is fluoro, bromo, chloro, or iodo. In other embodiments, the haloalkyl group is -L-C(X)(R′)—R², in which L is a covalent bond or an alkyl group, as defined herein; X is fluoro, bromo, chloro, or iodo; and each of R¹ and R² is, independently, H or alkyl, as defined herein.

By “haloheteroaliphatic” is meant a heteroaliphatic, as defined herein, in which one or more hydrogen atoms, such as one to 10 hydrogen atoms, independently is replaced with a halogen atom, such as fluoro, bromo, chloro, or iodo.

By “heteroaliphatic” is meant an aliphatic group, as defined herein, including at least one heteroatom to 20 heteroatoms, such as one to 15 heteroatoms, or one to 5 heteroatoms, which can be selected from, but not limited to oxygen, nitrogen, sulfur, silicon, boron, selenium, phosphorous, and oxidized forms thereof within the group. A heteroaliphatic group is unsubstituted or substituted, e.g., by a functional group described herein. For example, the heteroaliphatic group can be substituted with one or more substitution groups, as described herein for alkyl.

By “heteroaliphatic-carbonyl” is meant a heteroaliphatic group that is or can be coupled to a compound disclosed herein, wherein the heteroaliphatic group is or becomes coupled through a carbonyl group (—C(O)—). In some embodiments, the heteroaliphatic-carbonyl group is —C(O)—R, in which R is an optionally substituted heteroaliphatic group, as defined herein.

By “heteroaliphatic-carbonyloxy” is meant a heteroaliphatic group that is or can be coupled to a compound disclosed herein, wherein the heteroaliphatic group is or becomes coupled through a carbonyloxy group (—OC(O)—). In some embodiments, the heteroaliphatic-carbonyloxy group is —OC(O)—R, in which R is an optionally substituted heteroaliphatic group, as defined herein.

By “heteroaliphatic-oxy” is meant a heteroaliphatic group that is or can be coupled to a compound disclosed herein, wherein the heteroaliphatic group is or becomes coupled through an oxy group (—C(O)—). In some embodiments, the heteroaliphatic-oxy group is —O—R, in which R is an optionally substituted heteroaliphatic group, as defined herein.

By “heteroaliphatic-oxycarbonyl” is meant a heteroaliphatic group that is or can be coupled to a compound disclosed herein, wherein the heteroaliphatic group is or becomes coupled through an oxycarbonyl group (—C(O)O—). In some embodiments, the heteroaliphatic-oxycarbonyl group is —C(O)O—R, in which R is an optionally substituted heteroaliphatic group, as defined herein.

By “heteroalkyl,” “heteroalkenyl,” and “heteroalkynyl” is meant an alkyl, alkenyl, or alkynyl group (which can be branched, straight-chain, or cyclic), respectively, as defined herein, including at least one heteroatom to 20 heteroatoms, such as one to 15 heteroatoms, or one to 5 heteroatoms, which can be selected from, but not limited to, oxygen, nitrogen, sulfur, silicon, boron, selenium, phosphorous, and oxidized forms thereof within the group.

By “heteroalkylene,” “heteroalkenylene,” and “heteroalkynylene” is meant a multivalent (e.g., bivalent) form of a heteroalkyl, heteroalkenyl, or heteroalkynyl group, respectively, as described herein.

By “heteroaromatic” is meant an aromatic group, as defined herein, including at least one heteroatom to 20 heteroatoms, such as one to 15 heteroatoms, or one to 5 heteroatoms, which can be selected from, but not limited to oxygen, nitrogen, sulfur, silicon, boron, selenium, phosphorous, and oxidized forms thereof within the group. A heteroaromatic group is unsubstituted or substituted, e.g., by a functional group described herein. For example, the heteroaromatic group can be substituted with one or more substitution groups, as described herein for alkyl and/or aryl.

By “heteroaromatic-carbonyl” is meant a heteroaromatic group that is or can be coupled to a compound disclosed herein, wherein the heteroaromatic group is or becomes coupled through a carbonyl group (—C(O)—). In some embodiments, the heteroaromatic-carbonyl group is —C(O)—R, in which R is an optionally substituted heteroaromatic group, as defined herein.

By “heteroaromatic-carbonyloxy” is meant a heteroaromatic group that is or can be coupled to a compound disclosed herein, wherein the heteroaromatic group is or becomes coupled through a carbonyloxy group (—OC(O)—). In some embodiments, the heteroaromatic-carbonyloxy group is —OC(O)—R, in which R is an optionally substituted heteroaromatic group, as defined herein.

By “heteroaromatic-oxy” is meant a heteroaromatic group that is or can be coupled to a compound disclosed herein, wherein the heteroaromatic group is or becomes coupled through an oxy group (—O—). In some embodiments, the heteroaromatic-oxy group is —O—R, in which R is an optionally substituted heteroaromatic group, as defined herein.

By “heteroaromatic-oxycarbonyl” is meant a heteroaromatic group that is or can be coupled to a compound disclosed herein, wherein the heteroaromatic group is or becomes coupled through an oxycarbonyl group (—C(O)O—). In some embodiments, the heteroaromatic-carbonyl group is —C(O)O—R, in which R is an optionally substituted heteroaromatic group, as defined herein.

By “heteroaryl” is meant an aryl group including at least one heteroatom to six heteroatoms, such as one to four heteroatoms, which can be selected from, but not limited to, oxygen, nitrogen, sulfur, silicon, boron, selenium, phosphorous, and oxidized forms thereof within the ring. Such heteroaryl groups can have a single ring or multiple condensed rings, where the condensed rings may or may not be aromatic and/or contain a heteroatom, provided that the point of attachment is through an atom of the aromatic heteroaryl group. Heteroaryl groups may be substituted with one or more groups other than hydrogen, such as aliphatic, heteroaliphatic, aromatic, other functional groups, or any combination thereof. An exemplary heteroaryl includes a subset of heterocyclyl groups, as defined herein, which are aromatic, i.e., they contain 4n+2 pi electrons within the mono- or multicyclic ring system.

By “heteroarylene” is meant a multivalent (e.g., bivalent) form of a heteroaryl group, as described herein.

By “heteroatom” is meant an atom other than carbon, such as oxygen, nitrogen, sulfur, silicon, boron, selenium, or phosphorous. In particular disclosed embodiments, such as when valency constraints do not permit, a heteroatom does not include a halogen atom.

By “heterocyclyl” is meant a 5-, 6- or 7-membered ring, unless otherwise specified, containing one, two, three, or four non-carbon heteroatoms (e.g., independently selected from the group consisting of nitrogen, oxygen, phosphorous, sulfur, or halo). The 5-membered ring has zero to two double bonds and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. Heterocyclics include thiiranyl, thietanyl, tetrahydrothienyl, thianyl, thiepanyl, aziridinyl, azetidinyl, pyrrolidinyl, piperidinyl, azepanyl, pyrrolyl, pyrrolinyl, pyrazolyl, pyrazolinyl, pyrazolidinyl, imidazolyl, imidazolinyl, imidazolidinyl, pyridyl, homopiperidinyl, pyrazinyl, piperazinyl, pyrimidinyl, pyridazinyl, oxazolyl, oxazolidinyl, oxazolidonyl, isoxazolyl, isoxazolidiniyl, morpholinyl, thiomorpholinyl, thiazolyl, thiazolidinyl, isothiazolyl, isothiazolidinyl, indolyl, quinolinyl, isoquinolinyl, benzimidazolyl, benzothiazolyl, benzoxazolyl, furyl, thienyl, thiazolidinyl, isothiazolyl, isoindazoyl, triazolyl, tetrazolyl, oxadiazolyl, uricyl, thiadiazolyl, pyrimidyl, tetrahydrofuranyl, dihydrofuranyl, dihydrothienyl, dihydroindolyl, tetrahydroquinolyl, tetrahydroisoquinolyl, pyranyl, dihydropyranyl, tetrahydropyranyl, dithiazolyl, dioxanyl, dioxinyl, dithianyl, trithianyl, oxazinyl, thiazinyl, oxothiolanyl, triazinyl, benzofuranyl, benzothienyl, and the like.

By “heterocyclyloxy” is meant a heterocyclyl group, as defined herein, attached to the parent molecular group through an oxygen atom. In some embodiments, the heterocyclyloxy group is —O—R, in which R is a heterocyclyl group, as defined herein.

By “heterocyclyloyl” is meant a heterocyclyl group, as defined herein, attached to the parent molecular group through a carbonyl group. In some embodiments, the heterocyclyloyl group is —C(O)—R, in which R is a heterocyclyl group, as defined herein.

By “hydrazino” is meant —NR¹—NR²R³, where each of R¹, R², and R³ is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where a combination of R¹ and R² or a combination of R² and R³, taken together with the nitrogen atom to which each are attached, can form a heterocyclyl group, as defined herein. In some embodiments, each of R¹, R², or R³ is, independently, H, optionally substituted alkyl, optionally substituted aryl, optionally substituted alkyl-aryl, or optionally substituted aryl-alkyl. In particular embodiments, R² and R³ can be taken together, with the nitrogen atom to which each is attached, to form an optionally substituted heterocyclyl.

By “hydroxyl” is meant —OH.

By “hydroxyalkyl” is meant an alkyl group, as defined herein, substituted by one to three hydroxyl groups, with the proviso that no more than one hydroxyl group may be attached to a single carbon atom of the alkyl group and is exemplified by hydroxymethyl, dihydroxypropyl, and the like. In some embodiments, the hydroxyalkyl group is -L-OH, in which L is an alkyl group, as defined herein. In other embodiments, the hydroxyalkyl group is -L-C(OH)(R′)—R², in which L is a covalent bond or an alkyl group, as defined herein, and each of R¹ and R² is, independently, H or alkyl, as defined herein.

By “imidoyl” is meant a moiety including a carbonimidoyl group. In some embodiments, the imidoyl group is C(NR¹)R², in which each of R¹ and R² is, independently, selected from hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, optionally substituted silyloxy, as defined herein, or any combination thereof. In other embodiments, the imidoyl group is —C(NR¹)H, —C(NR¹)R^{Ak}, or —C(NR^{N1})R^{Ar}, in which R¹ is hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, or optionally substituted silyloxy; R^{Ak} is an optionally substituted alkyl or an optionally substituted aliphatic; and R^{Ar} is an optionally substituted aryl or an optionally substituted aromatic.

By “imino” is meant a —NR— group. In some embodiments, R is selected from hydrogen, optionally substituted aliphatic, optionally substituted heteroaliphatic, optionally substituted aromatic, or optionally substituted heteroaromatic. In particular embodiments, R is H, optionally substituted alkyl, optionally substituted alkoxy, optionally substituted aryl, optionally substituted aryloxy, optionally substituted alkyl-aryl, or optionally substituted aryl-alkyl.

By “isocyanato” is meant a —NCO group.

By “isocyano” is meant a —NC group.

By “ketone” is meant —C(O)R or a compound including such a group, where R is selected from aliphatic, heteroaliphatic, aromatic, as defined herein, or any combination thereof. An example of a ketone can include R¹C(O)R, in which each of R and R¹ is, independently, selected from aliphatic, haloaliphatic, haloheteroaliphatic, heteroaliphatic, aromatic, aliphatic-aromatic, heteroaliphatic-aromatic, as defined herein, or any combination thereof.

By “nitro” is meant an —NO₂ group.

By “nitroalkyl” is meant an alkyl group, as defined herein, substituted by one to three nitro groups. In some embodiments, the nitroalkyl group is -L-NO, in which L is an alkyl group, as defined herein. In other embodiments, the nitroalkyl group is -L-C(NO)(R′)—R², in which L is a covalent bond or an alkyl group, as defined herein, and each of R¹ and R² is, independently, H or alkyl, as defined herein.

By “oxo” is meant an ═O group.

By “oxy” is meant —O—.

By “perfluoroalkyl” is meant an alkyl group, as defined herein, having each hydrogen atom substituted with a fluorine atom. Exemplary perfluoroalkyl groups include trifluoromethyl, pentafluoroethyl, etc. In some embodiments, the perfluoroalkyl group is —(CF₂)ₙCF₃, in which n is an integer from 0 to 10.

By “perfluoroalkoxy” is meant an alkoxy group, as defined herein, having each hydrogen atom substituted with a fluorine atom. In some embodiments, the perfluoroalkoxy group is —O—R, in which R is a perfluoroalkyl group, as defined herein.

By “salt” is meant an ionic form of a compound or structure (e.g., any formulas, compounds, or compositions described herein), which includes a cation or anion compound to form an electrically neutral compound or structure. Salts are well known in the art. For example, non-toxic salts are described in Berge S. M. et al., “Pharmaceutical salts,” J. Pharm. Sci. 1977 January; 66(1):1-19; and in “Handbook of Pharmaceutical Salts: Properties, Selection, and Use,” Wiley-VCH, April 2011 (2nd rev. ed., eds. P. H. Stahl and C. G. Wermuth. The salts can be prepared in situ during the final isolation and purification of the compounds of the invention or separately by reacting the free base group with a suitable organic acid (thereby producing an anionic salt) or by reacting the acid group with a suitable metal or organic salt (thereby producing a cationic salt). Representative anionic salts include acetate, adipate, alginate, ascorbate, aspartate, benzenesulfonate, benzoate, bicarbonate, bisulfate, bitartrate, borate, bromide, butyrate, camphorate, camphorsulfonate, chloride, citrate, cyclopentanepropionate, digluconate, dihydrochloride, diphosphate, dodecylsulfate, edetate, ethanesulfonate, fumarate, glucoheptonate, gluconate, glutamate, glycerophosphate, hemisulfate, heptonate, hexanoate, hydrobromide, hydrochloride, hydroiodide, hydroxyethanesulfonate, hydroxynaphthoate, iodide, lactate, lactobionate, laurate, lauryl sulfate, malate, maleate, malonate, mandelate, mesylate, methanesulfonate, methylbromide, methylnitrate, methylsulfate, mucate, 2-naphthalenesulfonate, nicotinate, nitrate, oleate, oxalate, palmitate, pamoate, pectinate, persulfate, 3-phenylpropionate, phosphate, picrate, pivalate, polygalacturonate, propionate, salicylate, stearate, subacetate, succinate, sulfate, tannate, tartrate, theophyllinate, thiocyanate, triethiodide, toluenesulfonate, undecanoate, valerate salts, and the like. Representative cationic salts include metal salts, such as alkali or alkaline earth salts, e.g., barium, calcium (e.g., calcium edetate), lithium, magnesium, potassium, sodium, and the like; other metal salts, such as aluminum, bismuth, iron, and zinc; as well as nontoxic ammonium, quaternary ammonium, and amino cations, including, but not limited to ammonium, tetramethylammonium, tetraethylammonium, methylamine, dimethylamine, trimethylamine, triethylamine, ethylamine, pyridinium, and the like. Other cationic salts include organic salts, such as chloroprocaine, choline, dibenzylethylenediamine, diethanolamine, ethylenediamine, methylglucamine, and procaine. Yet other salts include ammonium, sulfonium, sulfoxonium, phosphonium, iminium, imidazolium, benzimidazolium, amidinium, guanidinium, phosphazinium, phosphazenium, pyridinium, etc., as well as other cationic groups described herein (e.g., optionally substituted isoxazolium, optionally substituted oxazolium, optionally substituted thiazolium, optionally substituted pyrrolium, optionally substituted furanium, optionally substituted thiophenium, optionally substituted imidazolium, optionally substituted pyrazolium, optionally substituted isothiazolium, optionally substituted triazolium, optionally substituted tetrazolium, optionally substituted furazanium, optionally substituted pyridinium, optionally substituted pyrimidinium, optionally substituted pyrazinium, optionally substituted triazinium, optionally substituted tetrazinium, optionally substituted pyridazinium, optionally substituted oxazinium, optionally substituted pyrrolidinium, optionally substituted pyrazolidinium, optionally substituted imidazolinium, optionally substituted isoxazolidinium, optionally substituted oxazolidinium, optionally substituted piperazinium, optionally substituted piperidinium, optionally substituted morpholinium, optionally substituted azepanium, optionally substituted azepinium, optionally substituted indolium, optionally substituted isoindolium, optionally substituted indolizinium, optionally substituted indazolium, optionally substituted benzimidazolium, optionally substituted isoquinolinum, optionally substituted quinolizinium, optionally substituted dehydroquinolizinium, optionally substituted quinolinium, optionally substituted isoindolinium, optionally substituted benzimidazolinium, and optionally substituted purinium).

By “silyl” is meant a —SiR¹R²R³ or —SiR¹R²— group. In some embodiments, each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyl group is —Si(R)ₐ(OR)_{b}(NR₂)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl.

By “silyloxy” is meant —OR, where R is an optionally substituted silyl group, as described herein. In some embodiments, the silyloxy group is —O—SiR¹R²R³, in which each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyloxy group is —O—Si(R)ₐ(OR)_{b}(NR₂)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl

By “sulfinyl” is meant an —S(O)— group.

By “sulfo” is meant an —S(O)₂OH group.

By “sulfonyl” or “sulfonate” is meant an —S(O)₂— group or a —SO₂R, where R is selected from hydrogen, aliphatic, heteroaliphatic, haloaliphatic, haloheteroaliphatic, aromatic, as defined herein, or any combination thereof.

By “thioalkyl” is meant an alkyl group, as defined herein, attached to the parent molecular group through a sulfur atom. Exemplary unsubstituted thioalkyl groups include C₁₋₆ thioalkyl. In some embodiments, the thioalkyl group is —S—R, in which R is an alkyl group, as defined herein.

By “thiol” is meant an —SH group.

A person of ordinary skill in the art would recognize that the definitions provided above are not intended to include impermissible substitution patterns (e.g., methyl substituted with 5 different groups, and the like). Such impermissible substitution patterns are easily recognized by a person of ordinary skill in the art. Any functional group disclosed herein and/or defined above can be substituted or unsubstituted, unless otherwise indicated therein.

As used herein, the term “about” means+/−10% of any recited value. As used herein, this term modifies any recited value, range of values, or endpoints of one or more ranges.

As used herein, the terms “top,” “bottom,” “upper,” “lower,” “above,” and “below” are used to provide a relative relationship between structures. The use of these terms does not indicate or require that a particular structure must be located at a particular location in the apparatus.

Other features and advantages of the invention will be apparent from the following description and the claims.

### Precursors

An aminosilane includes at least one nitrogen atom bonded to a silicon atom, but may also contain hydrogens, oxygens, halogens and carbons. Examples of aminosilanes are mono-, di-, tri- and tetra-aminosilane (H₃Si(NH₂)₄, H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, tert-butylsilanamine, bis(tertiarybutylamino)silane (SiH₂(NHC(CH₃)₃)₂ (BTBAS), tert-butyl silylcarbamate, SiH(CH₃)—(N(CH₃)₂)₂, SiHCl—(N(CH₃)₂)₂, (Si(CH₃)₂NH)₃, di(sec-butylamino)silane (DSBAS), di(isopropylamido)silane (DIPAS), bis(diethylamino)silane (BDEAS), and the like. A further example of an aminosilane is trisilylamine (N(SiH₃)₃).

A silicon-containing precursor can include one or more optionally substituted amino groups, thereby providing a non-limiting amino silane. In one embodiment, the precursor has a formula of (R′)₄₋ₓSi(NR″₂)ₓ, wherein:
x is 1, 2, 3, or 4;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl.

In another embodiment, the precursor has a formula of (R″₂N)ₓ(R′)₃₋ₓSi-L-Si(R′)₃₋ₓ(NR″₂)ₓ, wherein:
each x is, independently, 0, 1, 2, or 3;
L is a linker, such as a covalent bond, optionally substituted aliphatic, optionally substituted heteroaliphatic, optionally substituted aromatic, optionally substituted heteroaromatic, oxy (—O—), imino, or silyl;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl.

In particular embodiments, L is optionally substituted imino, such as —NR—, in which R is H, optionally substituted aliphatic, optionally substituted alkyl, optionally substituted alkenyl, optionally substituted alkynyl, or optionally substituted aromatic. In other embodiments, L is optionally substituted silyl, such as —SiR₂—, in which each R is, independently, H, optionally substituted aliphatic, optionally substituted alkyl, optionally substituted alkenyl, optionally substituted alkynyl, or optionally substituted aromatic.

In one instance, at least one x is not 0. In another embodiment, x can be 0 (e.g., if L includes a carbon atom or a heteroatom). In yet another embodiment, x is 0; and/or L includes optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino, or silyl.

In particular embodiments, at least one R′ or R″ is not H. The precursor can have any useful combination of R′ groups and amino groups (NR″₂) attached to one or more silicon atoms.

In some embodiments, R′ is H, optionally substituted amino (e.g., —NR₂), aliphatic-oxy (e.g., alkoxy or —OR), aliphatic-carbonyl (e.g., alkanoyl or —C(O)R), aliphatic-carbonyloxy (e.g., alkanoyloxy or —OC(O)R), aliphatic-oxycarbonyl (e.g., alkoxycarbonyl or —C(O)OR), silyl (e.g., —SiR₃), aliphatic-oxy-silyl (e.g., alkoxysilyl or —Si(R)ₐ(OR)_{b}), aminosilyl (e.g., —Si(R)ₐ(NR₂)_{b}), silyloxy (e.g., —O—SiR₃), aliphatic-oxy-silyloxy (e.g., alkoxysilyloxy or —O—Si(R)ₐ(OR)_{b}), aminosilyloxy (e.g., —O—Si(R)ₐ(NR₂)_{b}), aromatic (e.g., aryl), aromatic-oxy (e.g., aryloxy or —OR), hydroxyl (—OH), formyl (—C(O)H), and the like. In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic; a≥0; b≥1; and a+b=3. In some embodiments, two R groups can be taken together, with the nitrogen atom to which each is attached, to form an optionally substituted heterocyclyl. In other embodiments, each R is, independently, H, optionally substituted alkyl, optionally substituted alkenyl, optionally substituted alkynyl, or optionally substituted aryl.

In other embodiments, R″ is H, optionally substituted aliphatic, optionally substituted heteroaliphatic, optionally substituted alkyl, optionally substituted silyl, or optionally substituted silyloxy. In some embodiments, R″ is optionally substituted alkyl (e.g., Me, Et, nPr, iPr, sBu, or tBu). In other embodiments, R″ is —SiR′₃, —SiR₃, —Si(R′)ₐ(OR)_{b}, —Si(R)ₐ(OR)_{b}, —Si(R′)ₐ(NR₂)_{b}, —Si(R)ₐ(NR₂)_{b}, —Si(R′)ₐ(OR)_{b}(NR₂)_{c}, —Si(R)ₐ(OR)_{b}(NR₂)_{c}, —O—SiR′₃, —O—SiR₃, —O—Si(R′)ₐ(OR)_{b}, —O—Si(R)ₐ(OR)_{b}, —O—Si(R′)ₐ(NR₂)_{b}, —O—Si(R)ₐ(NR₂)_{b}, —O—Si(R′)ₐ(OR)_{b}(NR₂)_{c}, or —O—Si(R)ₐ(OR)_{b}(NR₂)_{c} in which each R′ is, independently, H, aliphatic, heteroaliphatic, aromatic, heteroaromatic, amino, hydrazino, azido, hydroxyl, silyl, silyloxy, cyanato, isocyanato, cyano, or isocyano, in which any of these may be optionally substituted; each R is, independently, H, optionally substituted aliphatic, optionally substituted heteroaliphatic, optionally substituted aromatic, or optionally substituted heteroaromatic; each of a, b, and c≥0; and a+b+c=3 or a+b=3 (if c is not present). In particular embodiments, R is H, optionally substituted alkyl, optionally substituted alkenyl, or optionally substituted alkynyl.

The precursor can include at least one R′ group attached to the silicon atom. In one embodiment, the precursor has a formula of (R′)(H)₃₋ₓSi(NR″₂)ₓ, wherein R′ and R″ can be any described herein, and wherein x is 1, 2, or 3. In another embodiment, the precursor has a formula of (R′)(H)₂Si(NR″₂), wherein R′ and R″ can be any described herein. In one embodiment, the precursor has a formula of (R′)(H)Si(NR″₂)₂, wherein R′ and R″ can be any described herein. In another embodiment, the precursor has a formula of (R′)₂(H)Si(NR″₂), wherein R′ and R″ can be any described herein. In yet another embodiment, the precursor has a formula of (R′)₂Si(NR″₂)₂, wherein R′ and R″ can be any described herein. In one embodiment, the precursor has a formula of (R′)₃Si(NR″₂), wherein R′ and R″ can be any described herein.

The precursor can lack an R′ group attached to the silicon atom. In one embodiment, the precursor has a formula of (H)₄₋ₓSi(NR″₂)ₓ, wherein each R″ can independently be any described herein, and wherein x is 1, 2, 3, or 4. In another embodiment, the precursor has a formula of Si(NR″₂)ₓ, wherein each R″ can independently be any described herein. In particular embodiments, each R″ is, independently, aliphatic, heteroaliphatic, aromatic, or heteroaromatic.

The precursor can include one or more hydrogen atoms attached to the silicon atom. In one embodiment, the precursor has a formula of (H)₃Si(NR″₂) or (H)₂Si(NR″₂)₂ or (H)Si(NR″₂)₃, wherein each R″ can independently be any described herein. In particular embodiments, each R″ is, independently, aliphatic, heteroaliphatic, aromatic, heteroaromatic, or amino, in which any of these may be optionally substituted.

The precursor can include a heterocyclyl group having a nitrogen atom. In one embodiment, the formula has a formula of H₃Si-Het, in which Het is an optionally substituted heterocyclyl including at least one nitrogen atom. In particular embodiments, the precursor has a formula of

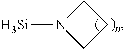

in which the heterocyclyl group can be optionally substituted (e.g., with any substituent described herein as a substitution for alkyl), and wherein n is 1, 2, 3, 4, or 5. In one embodiment, the formula has a formula of R′₃Si-Het, in which Het is an optionally substituted heterocyclyl including at least one nitrogen atom, and each R′ can independently be any described herein. In particular embodiments, the precursor has a formula of

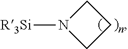

in which the heterocyclyl group can be optionally substituted (e.g., with any substituent described herein as a substitution for alkyl); each R′ can independently be any described herein; and wherein n is 1, 2, 3, 4, or 5.

In some instances, the precursor can have two or more silicon atoms, in which the precursor can include a Si—Si bond. In a particular embodiment, the precursor has a formula of (R″₂N)ₓ(R′)₃₋ₓSi—Si(R′)₃₋ₓ(NR″₂)ₓ, wherein R′ and R″ can be any described herein. In one embodiment, the precursor has a formula of (R″₂N)(R′)₂Si—Si(R′)₂(NR″₂), wherein R′ and R″ can be any described herein. In another embodiment, the precursor has a formula of (R″₂N)₂(R′)Si—Si(R′)(NR″₂)₂, wherein R′ and R″ can be any described herein. In yet another embodiment, the precursor has a formula of (R″₂N)₃Si—Si(NR″₂)₃, wherein each R″ can independently be any described herein.

The precursor can include differing groups attached to the silicon atoms. In one instance, the precursor has a formula of (R″₂N)ₓ(R′)₃₋ₓSi—SiH₃, wherein R′ and R″ can be any described herein.

A linker can be present between two silicon atoms. In one instance, the precursor has a formula of (R″₂N)ₓ(R′)₃₋ₓSi—NR—Si(R′)₃₋ₓ(NR″₂)ₓ, wherein R′ and R″ can be any described herein, and in which R is H, optionally substituted aliphatic, optionally substituted alkyl, optionally substituted alkenyl, optionally substituted alkynyl, or optionally substituted aromatic. In another instance, the precursor has a formula of (R″₂N)ₓ(H)₃₋ₓSi—NR—Si(H)₃₋ₓ(NR″₂)ₓ, wherein R, R′, and R″ can be any described herein.

The precursor can include a combination of R′ groups with a linker having a heteroatom. In one instance, the precursor has a formula of (R′)₃Si—NR—Si(R′)₃, wherein R and R′ can be any described herein. In another instance, the precursor has a formula of (R′)₃Si-L-Si(R′)₃, wherein L and R′ can be any described herein. In particular embodiments, L is oxy (—O—), optionally substituted imino (e.g., —NR—), or optionally substituted silyl (e.g., —SiR₂—).

The precursor can include any useful combination of R′ and NR″₂ groups in combination with two silicon atoms. In one instance, the precursor has a formula of (R″₂N)(R′)₂Si-L-Si(R′)₂(NR″₂)ₓ, wherein L, R′, and R″ can be any described herein.

The precursor can include heterocyclic groups including the silicon and nitrogen atoms. In one embodiment, the precursor has a formula of

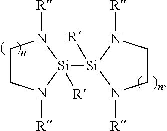

wherein R′ and R″ can be any described herein, and wherein n is 1, 2, 3, or 4.

In another embodiment, the precursor has a formula of

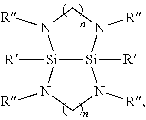

wherein R′ and R″ can be any described herein, and wherein n is 1, 2, 3, or 4. In yet another embodiment, the precursor has a formula of

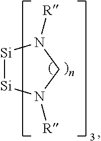

in which each R″ can independently be any described herein; and wherein n is 1, 2, 3, or 4.
In another embodiment, the precursor has a formula of

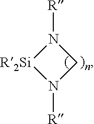

wherein R′ and R″ can be any described herein, and wherein n is 1, 2, 3, or 4. In yet another embodiment, the precursor has a formula of

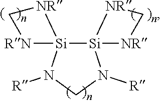

wherein R″ can independently be any described herein, and wherein n is 1, 2, 3, or 4.

In any precursor herein, two R″ can be taken together, with the nitrogen atom to which each is attached, to form an optionally substituted heterocyclyl.

Precursors can include any of the following, e.g., (R^{Ak})Si(NH₂)(NR^{Ak}₂)₂, (R^{Ak})Si(NR^{Ak}₂)₃, (R^{Ak})₂Si(NHR^{Ak}₂)₂, (R^{Ak})(H)Si(NHR^{Ak})₂, (R^{Ak})₃Si(NR^{Ak}₂), (R^{Ak})₃Si(NHR^{Ak}), H₂Si(NHR^{Ak}₂)₂, (R^{Ak})(H)Si(NR^{Ak}₂)₂, HSi(NH₂)(NR^{Ak}₂)₂, HSi(NR^{Ak}₂)₃, Si(NR^{Ak}₂)₄, (R′)(H)Si(NR″₂)₂, (R′)₂Si(NR^{Ak}₂)₂, (R′)₂Si(N[SiH_{3]2})₂, (R′)₂Si(N[SiR″_{3]2})₂, or (R′)₃Si(NHR^{Ak}). In some embodiments, each of R′ and R″, independently, can be any described herein (e.g., H, optionally substituted aliphatic, optionally substituted heteroaliphatic, optionally substituted alkyl, optionally substituted alkenyl, or optionally substituted alkynyl). In other embodiments, each R^{Ak} is, independently, H, optionally substituted aliphatic, optionally substituted heteroaliphatic, optionally substituted alkyl, optionally substituted alkenyl, or optionally substituted alkynyl. In particular embodiments, R^{Ak} is methyl (Me), ethyl (Et), n-propyl (nPr), iso-propyl (iPr), n-butyl (nBu), sec-butyl (sBu), iso-butyl (iBu), tert-butyl (tBu), and the like.

Non-limiting examples of precursor include any of the following: methylaminotrimethylsilane (SiMe₃[NHMe]); dimethylaminodimethylsilane (SiMe₂H[NMe₂]); dimethylaminotrimethylsilane (SiMe₃[NMe₂]); dimethylaminodiethylsilane (SiHEt₂[NMe₂]); dimethylaminotriethylsilane (SiEt₃[NMe₂]); ethylmethylaminodimethylsilane (SiHMe₂[NMeEt]); ethylmethylaminotrimethylsilane (SiMe₃[NMeEt]); ethylmethylaminodiethylsilane (SiHEt₂[NMeEt]); ethylmethylaminotriethylsilane (SiEt₃[NMeEt]); diethylaminomethylsilane (SiH₂Me[NEt₂]); diethylaminoethylsilane (SiH₂Et[NEt₂]); ethylaminotrimethylsilane (SiMe₃[NHEt]); diethylaminodimethylsilane (SiHMe₂[NEt₂]); diethylaminodiethylsilane (SiHEt₂[NEt₂]); diethylaminotrimethylsilane (SiMe₃[NEt₂]); diethylaminotriethylsilane (SiEt₃[NEt₂]); iso-propylaminodimethylsilane (SiHMe₂[NHiPr]); iso-propylaminotrimethylsilane (SiMe₃[NHiPr]); iso-propylaminodiethylsilane (SiHEt₂[NHiPr]); iso-propylaminotriethylsilane (SiEt₃[NHiPr]); di-isopropylaminotrimethylsilane (SiMe₃[NiPr₂]); di-iso-propylaminosilane (SiH₃[NiPr₂], C₆H₁₇NSi, or DIPAS); di-iso-propylaminomethylsilane (SiH₂Me[NiPr₂]); di-isopropylaminodimethylsilane (SiHMe₂[NiPr₂]); di-isopropylaminodiethylsilane (SiHEt₂[NiPr₂]); di-isopropylaminotriethylsilane (SiEt₃[NiPr₂]); n-propylaminotrimethylsilane (SiMe₃[NHnPr]); di-sec-butylaminosilane (SiH₃[NsBu₂] or DSBAS); di-sec-butylaminomethylsilane (SiH₂Me[NsBu₂]); iso-butylaminotrimethylsilane (SiMe₃[NHiBu]); n-butylaminotrimethylsilane (SiMe₃[NHnBu]); tert-butylaminodimethylsilane (SiHMe₂[NHtBu]); tert-butylaminotrimethylsilane (SiMe₃[NHtBu]); tert-butylaminodiethylsilane (SiHEt₂[NHtBu]); tert-butylaminotriethylsilane (SiEt₃[NHtBu]); dicyclohexylaminosilane (SiH₃[NCy₂], in which Cy is cyclohexyl); N-propylisopropylaminosilane (SiH₃[NiPmPr]); N-methylcyclohexylaminosilane (SiH₃[NMeCy]); N-ethylcyclohexylaminosilane (SiH₃[NEtCy]); allylphenylaminosilane (SiH₃[NAllPh]); N-isopropylcyclohexylaminosilane (SiH₃[NiPrCy]); allylcyclopentylaminosilane (SiH₃[NAllCp]); phenylcyclohexylaminosilane (SiH₃[NPhCy]); cyclohexylaminotrimethylsilane (SiMe₃[NHCy], in which Cy is cyclohexyl); pyrrolyltrimethylsilane (SiMe₃[NHPy], in which Py is pyrrolyl); pyrrolidinotrimethylsilane (SiMe₃[NHPyr], in which Pyr is pyrrolindyl); piperidino trimethylsilane (SiMe₃[NHPip], in which Pip is piperidinyl); piperazinotrimethylsilane (SiMe₃[NHPz], in which Pz is piperazinyl); imidazolyltrimethylsilane (SiMe₃[NHIm], in which Im is imidazolyl); bis(dimethylamino)silane (SiH₂[NMe₂]₂ or BDMAS); bis(dimethylamino) methylsilane (SiMeH[NMe₂]₂); bis(dimethylamino)dimethylsilane (SiMe₂[NMe₂]₂ or BDMADMS); bis(dimethylamino)diethylsilane (SiEt₂[NMe₂]₂); bis(dimethylamino) methylvinylsilane (SiMeVi[NMe₂]₂); bis(ethylamino)dimethylsilane (SiMe₂[NHEt]2); bis(ethylmethylamino)silane (SiH₂[NMeEt]2); bis(ethylmethylamino)dimethylsilane (SiMe₂[NMeEt]2); bis(ethylmethylamino)diethylsilane (SiEt₂[NMeEt]2); bis(ethylmethylamino) methylvinylsilane (SiMeVi[NMeEt]2); bis(diethylamino)silane (SiH₂[NEt₂]₂, C₈H₂₂N₂Si, or BDEAS); bis(diethylamino)dimethylsilane (SiMe₂[NEt₂]₂); bis(diethylamino)methylvinylsilane (SiMeVi[NEt₂]₂); bis(diethylamino)diethylsilane (SiEt₂[NEt₂]₂); bis(iso-propylamino) dimethylsilane (SiMe₂[NHiPr]2); bis(iso-propylamino)diethylsilane (SiEt₂[NHiPr]2); bis(iso-propylamino)methylvinylsilane (SiMeVi[NHiPr]2); bis(di-iso-propylamino)silane (SiH₂[NiPr₂]₂); bis(di-iso-propylamino)dimethylsilane (SiMe₂[NiPr₂]₂); bis(di-iso-propylamino) diethylsilane (SiEt₂[NiPr₂]₂); bis(di-iso-propylamino)methylvinylsilane (SiMeVi[NiPr₂]₂); bis(methylamino)silane (SiH₂[NHMe]2); bis(sec-butylamino)silane (SiH₂[NHsBu]2); bis(sec-butylamino)methylsilane (SiHMe[NHsBu]₂); bis(sec-butylamino)ethylsilane (SiHEt[NHsBu]₂); bis(tert-butylamino)silane (SiH₂[NHtBu]₂ or BTBAS); bis(tert-butylamino)dimethylsilane (SiMe₂[NHtBu]₂); bis(tert-butylamino) methylvinylsilane (SiMeVi[NHtBu]₂); bis(tert-butylamino)diethylsilane (SiEt₂[NHtBu]₂); bis(1-imidazolyl)dimethylsilane (SiMe₂[Im]₂, in which Im is imidazolyl); tris(dimethylamino)silane (SiH[NMe₂]₃ or 3DMAS); tris(dimethylamino)phenylsilane (SiPh[NMe₂]₃); tris(dimethylamino) methylsilane (SiMe[NMe₂]₃); tris(dimethylamino)ethylsilane (SiEt[NMe₂]₃); tris(ethylmethylamino)silane (SiH[NEtMe]₃); tris(diethylamino)silane (SiH[NEt₂]₃); tris(iso-propylamino)silane (SiH[NHiPr]₃, C₉H₂₅N₃Si, or TIPAS); tris(dimethylamino)silylamide (Si[NMe₂]₃[NH₂]); tetrakis(dimethylamino)silane (Si[NMe₂]₄); tetrakis(ethylmethylamino)silane (Si[NEtMe]₄); tetrakis(diethylamino)silane (Si[NEt₂]₄); 1,2-diethyl-tetrakis(diethylamino) disilane ([Et₂N]₂EtSi—SiEt[NEt₂]₂); 1,2-dimethyl-tetrakis(dimethylamino)disilane ([Me₂N]₂MeSi—SiMe[NMe₂]₂); 1,2-dimethyl-tetrakis(diethylamino)disilane ([Et₂N]₂MeSi—SiMe[NEt₂]₂); hexakis(methylamino)disilane ([MeHN]₃Si—Si[NHMe]₃); hexakis(ethylamino)disilane ([EtHN]₃Si—Si[NHEt]₃); hexakis(dimethylamino)disilazane (Me₂N—Si[NMe₂]₂—Si[NMe₂]₂—NMe₂), and the like.

In some embodiments, the silane precursor is a halosilane precursor. A halosilane precursor is defined as a precursor having at least one halogen-containing atom and at least one silicon atom. Halogens include chlorine, fluorine, bromine, and iodine. In some embodiments, the halosilane precursor includes a structure of formula (I):

Si(X)₄,
wherein at least one X includes a halogen atom.

For example, one halosilane is tetrachlorosilane or silicon tetrachloride (SiCl₄). Another example of a chemical formula of a halosilane is SiₙX_{y}H_{z} where X is a halogen and H is hydrogen; n is an integer greater than or equal to 1 and is equal to the number of Si atoms in the molecule; in some embodiments, y is about 1 to about 4, and z is 4−y. Additional examples include but are not limited to SiHCl₃, SiH₂Cl₂, and SiH₃Cl.

Examples of halosilanes are iodosilanes, bromosilanes, chlorosilanes and fluorosilanes. Specific chlorosilanes include but are not limited to tetrachlorosilane, trichlorosilane, dichlorosilane (DCS), monochlorosilane, chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, thexyldimethylchlorosilane, hexachlorodisilane (HCDS), and the like.

In some embodiments, the halosilane is carbon-free. In some embodiments, the halosilane is an organic silicon-containing precursor.

In some embodiments, the halosilane precursor (e.g., in formula (I)) has at least one optionally substituted C₁₋₂ haloalkyl group. Non-limiting haloaliphatic groups include —CX_{y}H_{3-y}, wherein y is 1, 2, or 3, and wherein each X is, independently, halo (F, Cl, Br, or I); —CX_{z}H_{2-z}CX_{y}H_{3-y}, wherein z is 0, 1, or 2, wherein y is 0, 1, 2, or 3, and wherein each X is, independently, halo (F, Cl, Br, or I), in which at least one of z or y is not 0; or —CH₂CX_{y}H_{3-y}, wherein y is 1, 2, or 3, and wherein each X is, independently, halo (F, Cl, Br, or I). Yet other non-limiting haloalkyl groups include fluoromethyl (—CH₂F), difluoromethyl (—CHF₂), trifluoromethyl (—CF₃), chloromethyl (—CH₂Cl), dichloromethyl (—CHCl₂), trichloromethyl (—CCl₃), bromomethyl (—CH₂Br), dibromomethyl (—CHBr₂), tribromomethyl (—CBr₃), iodomethyl (—CH₂I), diiodomethyl (—CHI₂), triiodomethyl (—CI₃), bromofluoromethyl (—CHFBr), chlorofluoromethyl (—CHFCl), fluoroiodomethyl (—CHFI), 2-fluoroethyl (—CH₂CH₂F), 2-chloroethyl (—CH₂CH₂Cl), 2-bromoethyl (—CH₂CH₂Br), 2-iodoethyl (—CH₂CH₂I), 2,2-difluoroethyl (—CH₂CHF₂), 2,2-dichloroethyl (—CH₂CHCl₂), 2,2-dibromoethyl (—CH₂CHBr₂), 2,2-diiodoethyl (—CH₂CHI₂), 2,2-fluoroiodoethyl (—CH₂CHFI), and the like. In particular embodiments, the C₁₋₂ haloalkyl includes 3-halo-substituted ethyl. Yet other haloaliphatic groups include C₁₋₄ haloalkyl, C₂₋₄ haloalkenyl, and C₂₋₄ haloalkynyl.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method for processing substrates, the method comprising:
depositing a sacrificial layer directly on exposed surfaces of a mandrel on a semiconductor substrate; and
introducing a spacer material precursor and oxygen-containing reactant and igniting a first plasma to simultaneously remove the sacrificial layer and deposit a spacer material on the exposed surfaces of the mandrel.

2. The method of claim 1, wherein the sacrificial layer comprises carbon.

3. The method of claim 1, wherein the sacrificial layer is deposited by plasma-enhanced chemical vapor deposition.

4. The method of claim 1, wherein the sacrificial layer is deposited conformally.

5. The method of claim 1, wherein the sacrificial layer is deposited to preferentially deposit thicker sacrificial layer material at or near the top of the mandrel than a bottom of the mandrel.

6. The method of claim 1, wherein the sacrificial layer has a density less than a density of the mandrel.

7. The method of claim 1, wherein the sacrificial layer has a modulus less than a modulus of the mandrel.

8. The method of claim 1, wherein the sacrificial layer is deposited using a carbon-containing precursor.

9. An apparatus comprising:
a process chamber comprising a heated pedestal for holding a substrate;
one or more gas sources for each containing one or more gases selected from the group consisting of carbon-containing gases, silicon-containing gases, and oxygen-containing gases;
at least one outlet for coupling to a vacuum; and
a controller for controlling operations in the apparatus, comprising machine-readable instructions for:
(i) causing introduction of a carbon-containing gas at a pedestal temperature of less than about 50° C.;
(ii) after causing introduction of the carbon-containing gas, causing introduction of a silicon-containing precursor and an oxygen-containing reactant while maintaining the same pedestal temperature; and
(iii) generating a plasma while the oxygen-containing reactant is introduced.

10. A method for processing substrates, the method comprising:
providing a semiconductor substrate;
depositing one or more layers of spacer material on the semiconductor substrate using atomic layer deposition,
wherein atomic layer deposition is performed in cycles, a cycle comprising exposing the semiconductor substrate to a deposition precursor to adsorb the deposition precursor to a surface of the substrate to form an adsorbed deposition precursor and converting the adsorbed deposition precursor to spacer material using a first plasma ignited using a plasma power of less than about 500 W; and
after at least one cycle atomic layer deposition, exposing the spacer material to a second plasma at a plasma energy of greater than about 25000 J to form a densified spacer material.
